(19) United States
(12) Patent Application Publication
(10) Pub. No.: US 2026/0202929 A1
(43) Pub. Date: Jul. 16, 2026

(54) ELECTRONIC DEVICE

(71) Applicant: Samsung Display Co., Ltd., Yongin-si (KR)

(72) Inventors: HYUNGBAE KIM, Yongin-si (KR); SANGHYUN LIM, Yongin-si (KR); Hyunjee JEON, Yongin-si (KR)

(21) Appl. No.: 19/374,440

(22) Filed: Oct. 30, 2025

(30) Foreign Application Priority Data
Jan. 14, 2025 (KR) 10-2025-0005557

(51) Int. Cl. G06F 3/041; G06F 3/044; H10K 59/131; H10K 59/40

(52) U.S. Cl. CPC G06F 3/04164; G06F 3/0446; H10K 59/131; H10K 59/40; G06F 2203/04111; G06F 2203/04112; G06F 2203/04114

(57) ABSTRACT

Provided is an electronic device including a display layer, and a sensor layer above the display layer and including first electrodes arranged along a first direction, second electrodes crossing the first electrodes and arranged along a second direction crossing the first direction, a first auxiliary electrode group including first auxiliary electrodes arranged along the second direction, and a first auxiliary trace line electrically connected to the first auxiliary electrodes, and a second auxiliary electrode group having an impedance that is substantially equal to an impedance of the first auxiliary electrode group, and including second auxiliary electrodes arranged along the second direction, and a second auxiliary trace line electrically connected to the second auxiliary electrodes.

### CROSS-REFERENCE TO RELATED APPLICATIONS

The present application claims priority to, and the benefit of, Korean Patent Application No. 10-2025-0005557, filed on January 14, 2025, the entire contents of which are hereby incorporated by reference.

### BACKGROUND

The present disclosure herein relates to an electronic device with improved touch reliability.

Multimedia electronic devices, such as televisions, mobile phones, tablet computers, laptops, navigation devices, and game consoles, include display devices for displaying images. Such an electronic device may include a sensor layer (or an input sensor) capable of providing a touch-based input method, allowing the user to input information or commands suitably, intuitively, and conveniently, in addition to conventional input methods, such as buttons, keyboards, and mice. The sensor layer may sense a user's touch or pressure. In recent years, there has been an increasing demand for using a pen for precise touch input among users accustomed to inputting information using a stylus or for corresponding applications, such as sketching or drawing applications.

### SUMMARY

The present disclosure provides an electronic device with improved touch reliability.

One or more embodiments of the present disclosure provide an electronic device including a display layer, and a sensor layer above the display layer and including first electrodes arranged along a first direction, second electrodes crossing the first electrodes and arranged along a second direction crossing the first direction, a first auxiliary electrode group including first auxiliary electrodes arranged along the second direction, and a first auxiliary trace line electrically connected to the first auxiliary electrodes, and a second auxiliary electrode group having an impedance that is substantially equal to an impedance of the first auxiliary electrode group, and including second auxiliary electrodes arranged along the second direction, and a second auxiliary trace line electrically connected to the second auxiliary electrodes.

The sensor layer may further include a first pad connected to the first auxiliary trace line, and a second pad connected to the second auxiliary trace line, wherein the second auxiliary electrodes are between the first auxiliary electrodes and a pad area at which the first pad and the second pad are located.

The first auxiliary electrodes may include a first auxiliary electrode, wherein the second auxiliary electrodes include a second auxiliary electrode, wherein the first electrodes include a first electrode crossing the first auxiliary electrode and the second auxiliary electrode, and wherein the second electrodes include a (2-1)-th electrode overlapping the first auxiliary electrode, and a (2-2)-th electrode overlapping the second auxiliary electrode.

A resistance of the first auxiliary electrode may be substantially equal to a resistance of the second auxiliary electrode, wherein a resistance of the first auxiliary trace line is substantially equal to a resistance of the second auxiliary trace line.

A capacitance between the first auxiliary electrode and the first electrode may be substantially equal to a capacitance between the second auxiliary electrode and the first electrode.

A capacitance between the first auxiliary electrode and the (2-1)-th electrode may be substantially equal to a capacitance between the second auxiliary electrode and the (2-2)-th electrode.

A first base capacitance corresponding to the first auxiliary electrode may be substantially equal to a second base capacitance corresponding to the second auxiliary electrode.

The first auxiliary trace line may have a resistance that is greater than a resistance of the second auxiliary trace line, wherein the first auxiliary electrode has a resistance that is less than a resistance of the second auxiliary electrode.

A resistance of the first auxiliary trace line may be greater than a resistance of the second auxiliary trace line, wherein a capacitance corresponding to the first auxiliary electrode is less than a capacitance corresponding to the second auxiliary electrode.

A capacitance between the first auxiliary electrode and the first electrode may be less than a capacitance between the second auxiliary electrode and the first electrode.

A capacitance between the first auxiliary electrode and the (2-1)-th electrode may be less than a capacitance between the second auxiliary electrode and the (2-2)-th electrode.

A first base capacitance corresponding to the first auxiliary electrode may be less than a second base capacitance corresponding to the second auxiliary electrode.

The first auxiliary electrode may have a first mesh structure, wherein the second auxiliary electrode has a second mesh structure, wherein, within a region, a surface area occupied by the first mesh structure is greater than a surface area occupied by the second mesh structure.

The first auxiliary electrode may include a first auxiliary pattern, and an additional auxiliary pattern at a different layer from a layer at which the first auxiliary pattern is located, and electrically connected to the first auxiliary pattern.

The sensor layer may further include an insulating layer, wherein the first electrode includes first sensing patterns above the insulating layer, and a first bridge pattern between the insulating layer and the display layer and connected to the first sensing patterns, wherein the second auxiliary electrode includes a (2-1)-th layer auxiliary electrode between the insulating layer and the display layer, and a (2-2)-th layer auxiliary electrode above the (2-1)-th layer auxiliary electrode, and wherein a capacitance between the first auxiliary electrode and the first electrode is less than a capacitance between the second auxiliary electrode and the first electrode.

The insulating layer may include an organic layer.

A portion of the second auxiliary electrode between the display layer and the insulating layer may have a surface area that is greater than a surface area of a portion of the first auxiliary electrode between the display layer and the insulating layer.

The electronic device may further include a sensor driver configured to drive the sensor layer, wherein the sensor layer further includes third electrodes arranged along the first direction to overlap the first electrodes, and wherein the sensor driver is further configured to selectively operate in a first mode for sensing a touch input, and a second mode for sensing a pen input and including a charging driving mode wherein the sensor driver is configured to provide a first signal to at least one of the third electrodes, and to provide a second signal to at least another one of the third electrodes, and a pen-sensing driving mode wherein the sensor driver is configured to receive first reception signals from the first electrodes, and to receive second reception signals from the second electrodes.

In one or more embodiments of the present disclosure, an electronic device includes first electrodes, second electrodes crossing the first electrodes, a first auxiliary electrode group including first auxiliary electrodes, and a first auxiliary trace line electrically connected to the first auxiliary electrodes, and a second auxiliary electrode group having an impedance that is substantially equal to an impedance of the first auxiliary electrode group, and including second auxiliary electrodes, and a second auxiliary trace line electrically connected to the second auxiliary electrodes.

A resistance of the first auxiliary electrode group may be substantially equal to a resistance of the second auxiliary electrode group, and a capacitive reactance of the first auxiliary electrode group is substantially equal to a capacitive reactance of the second auxiliary electrode group, or the first auxiliary electrode group may have resistance that is greater than a resistance of the second auxiliary electrode group, and the first auxiliary electrode group has a capacitive reactance that is less than a capacitive reactance of the second auxiliary electrode group.

### BRIEF DESCRIPTION OF THE FIGURES

The accompanying drawings are included to provide a further understanding of the present disclosure, and are incorporated in and constitute a part of this specification. The drawings illustrate embodiments of the present disclosure and, together with the description, serve to explain aspects of the present disclosure. In the drawings:

FIG. 1 is a block diagram of an electronic device according to one or more embodiments;

FIG. 2A is a perspective view of the electronic device according to one or more embodiments of the present disclosure;

FIG. 2B is a rear perspective view of the electronic apparatus according to one or more embodiments of the present disclosure;

FIG. 3 is a perspective view of an electronic device according to one or more embodiments of the present disclosure;

FIG. 4 is a perspective view of an electronic device according to one or more embodiments of the present disclosure;

FIG. 5 is a schematic cross-sectional view of a display device according to one or more embodiments of the present disclosure;

FIG. 6 is a diagram for explaining the operation of an electronic device according to one or more embodiments of the present disclosure;

FIG. 7A is a cross-sectional view of the display panel according to one or more embodiments of the present disclosure;

FIG. 7B is a cross-sectional view illustrating a portion of components of a sensor layer according to one or more embodiments of the present disclosure;

FIG. 8 is a plan view of the sensor layer according to one or more embodiments of the present disclosure;

FIG. 9A is a plan view illustrating a first conductive layer of a sensing unit according to one or more embodiments of the present disclosure;

FIG. 9B is an enlarged plan view of an XX' area shown in FIG. 9A;

FIG. 10A is a plan view illustrating a second conductive layer of the sensing unit according to one or more embodiments of the present disclosure;

FIG. 10B is an enlarged view of an area YY’ of FIG. 10A;

FIG. 11 is a plan view illustrating a portion of components of the sensing unit according to one or more embodiments of the present disclosure;

FIG. 12 is a view of capacitors located on the sensor layer according to one or more embodiments of the present disclosure;

FIG. 13 is a plan view illustrating a portion of components of the sensor layer according to one or more embodiments of the present disclosure;

FIG. 14 is a plan view illustrating a portion of the components of the sensor layer according to one or more embodiments of the present disclosure;

FIG. 15 is a plan view illustrating a portion of the components of the sensor layer according to one or more embodiments of the present disclosure;

FIG. 16A is a plan view illustrating a portion of the components of the sensor layer according to one or more embodiments of the present disclosure;

FIG. 16B is a plan view illustrating a portion of the components of the sensor layer according to one or more embodiments of the present disclosure;

FIG. 16C is a cross-sectional view illustrating a portion of the components of the sensor layer according to one or more embodiments of the present disclosure;

FIG. 17A is a plan view illustrating a portion of the components of a sensor layer according to one or more embodiments of the present disclosure;

FIG. 17B is a plan view illustrating a portion of the components of the sensor layer according to one or more embodiments of the present disclosure;

FIG. 17C is a plan view illustrating a portion of the components of the sensor layer according to one or more embodiments of the present disclosure;

FIG. 18A is a plan view illustrating a portion of the components of a sensor layer according to one or more embodiments of the present disclosure;

FIG. 18B is a plan view illustrating a portion of the components of the sensor layer according to one or more embodiments of the present disclosure;

FIG. 19 is a cross-sectional view illustrating a portion of the components of the sensor layer and a second electrode according to one or more embodiments of the present disclosure;

FIG. 20 is a view for explaining the operation of a sensor driver according to one or more embodiments of the present disclosure;

FIG. 21 is a view for explaining the operation of a sensor driver according to one or more embodiments of the present disclosure;

FIG. 22 is a view for explaining a first mode according to one or more embodiments of the present disclosure;

FIG. 23 is a view for explaining a second mode according to one or more embodiments of the present disclosure;

FIG. 24A is a graph illustrating the waveform of a first signal according to one or more embodiments of the present disclosure;

FIG. 24B is a graph illustrating the waveform of a second signal according to one or more embodiments of the present disclosure;

FIG. 25A is a view for explaining a second mode according to one or more embodiments of the present disclosure; and

FIG. 25B is a view for explaining a second mode based on a single sensing unit according to one or more embodiments of the present disclosure.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature’s relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When "C to D" is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer, or section described below could be termed a second element, component, region, layer, or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/- 5 % of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ± 30%, 20%, 10%, 5% of the stated value. Further, the use of “may” when describing embodiments of the present disclosure refers to “one or more embodiments of the present disclosure.” Furthermore, the expression “being the same” may mean “being substantially the same.” In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Hereinafter, embodiments of the present disclosure are described with reference to the drawings.

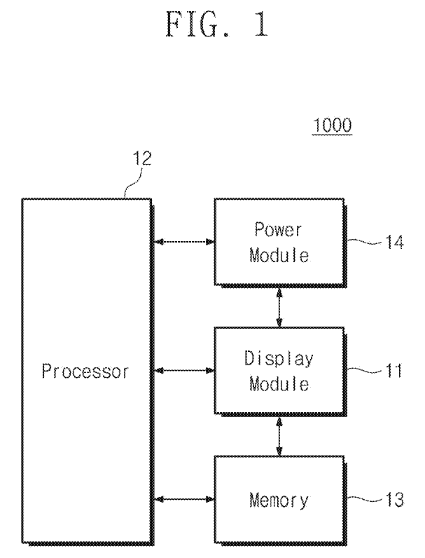

FIG. 1 is a block diagram of an electronic device 1000 according to one or more embodiments.

Referring to FIG. 1, the electronic device 1000 may include a display module 11, a processor 12, a memory 13, and a power module 14.

The display module 11 may display an image. The image may include both a dynamic image and a still image. The processor 12 may include at least one of a central processing unit CPU, an application processor AP, a graphic processing unit GPU, a communication processor CP, an image signal processor ISP, or a controller. The processor 12 may be configured to control the operation of the display module 11.

The memory 13 may store data information necessary for the operation of the processor 12 or the display module 11. When the processor 12 executes an application stored in the memory 13, an image data signal and/or an input control signal may be transmitted to the display module 11, and the display module 11 may process the received signal to output image information through a display screen.

The power module 14 may include a power supply module, such as a power adapter or a battery device, and a power conversion module that converts the power supplied by the power supply module to generate the power required for the operation of the electronic device 1000.

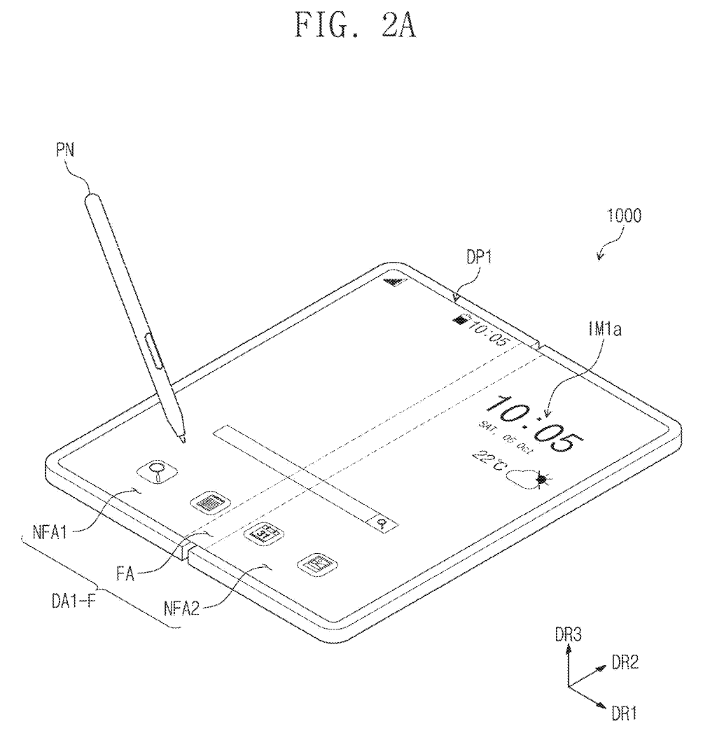

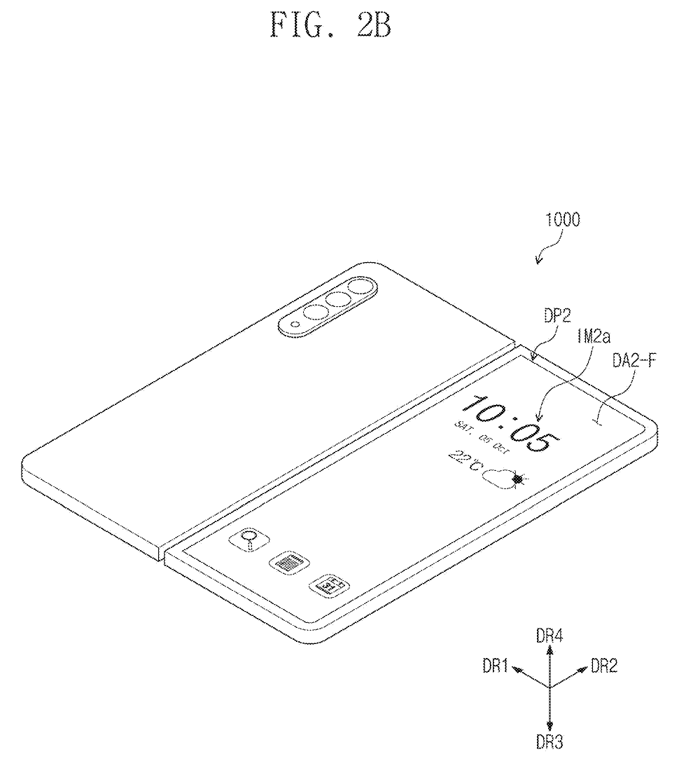

FIG. 2A is a perspective view of the electronic device 1000 according to one or more embodiments of the present disclosure. FIG. 2B is a rear perspective view of the electronic device according to one or more embodiments of the present disclosure.

Referring to FIGS. 2A and 2B, the electronic device 1000 may be a device activated in response to an electrical signal. For example, the electronic device 1000 may display an image and sense inputs applied from an external source. The external input may be a user input. The user input may include various types of external inputs, such as a part of the user's body, a pen PN, light, heat, or pressure.

The electronic device 1000 may include a first display panel DP1 and a second display panel DP2. The first display panel DP1 and the second display panel DP2 may be separate and independent panels. The first display panel DP1 may be referred to as a main display panel, and the second display panel DP2 may be referred to as an auxiliary display panel or an external display panel.

The first display panel DP1 may include a first display area DA1-F, and the second display panel DP2 may include a second display area DA2-F. The second display panel DP2 may have a surface area that is less than that of the first display panel DP1. The first display area DA1-F may have a surface area greater than that of the second display area DA2-F, corresponding to the sizes of the first display panel DP1 and the second display panel DP2.

When the electronic device 1000 is in an unfolded state, the first display area DA1-F may have a plane that is substantially parallel to a first direction DR1 and to a second direction DR2. A thickness direction of the electronic apparatus 1000 may be parallel to a third direction DR3 that crosses the first direction DR1 and the second direction DR2. Thus, a front surface (or a top surface) and a rear surface (or a bottom surface) of members constituting the electronic apparatus 1000 may be defined by the third direction DR3.

The first display panel DP1 or the first display area DA1-F may include a folding area FA that is folded and unfolded, and a plurality of non-folding areas NFA1 and NFA2 spaced apart from each other with the folding area FA in between. The second display panel DP2 may overlap any one of the plurality of non-folding areas NFA1 and NFA2. For example, the second display panel DP2 may overlap the first non-folding area NFA1.

A portion of the first display panel DP1, for example, a display direction of a first image IM1a displayed in the second non-folding area NFA2, and a display direction of a second image IM2a displayed in the second display panel DP2, may be in opposite directions. For example, the first image IM1a may be displayed in a third direction DR3, and the second image IM2a may be displayed in a fourth direction DR4, which is opposite to the third direction DR3.

In one or more embodiments of the present disclosure, the folding area FA may be bent about a folding axis extending in a direction parallel to a long side of the electronic device 1000, for example, in a direction parallel to a second direction DR2. When the electronic device 1000 is in a folded state, the folding area FA may have a corresponding curvature and curvature radius. The first non-folding area NFA1 and the second non-folding area NFA2 may face each other, and the electronic device 1000 may be inner-folded so that the first display area DA1-F is not exposed to the outside.

In one or more embodiments of the present disclosure, the electronic device 1000 may be outer-folded so that the first display area DA1-F is exposed to the outside. In one or more embodiments of the present disclosure, the electronic device 1000 may be capable of both inner-folding and outer-folding in an unfolded state; however, it is not limited thereto.

FIG. 2A illustrates an example in which a single folding area FA is defined (provided or included) in the electronic device 1000, but it is not limited thereto. For example, a plurality of folding axes and a plurality of folding areas corresponding to the plurality of folding axes may be defined in the electronic device 1000, and the electronic device 1000 may be inner-folded or outer-folded in an unfolded state at each of the plurality of folding areas.

According to one or more embodiments of the present disclosure, at least one of the first display panel DP1 or the second display panel DP2 may sense an input by a pen PN even without including a digitizer. Accordingly, because the digitizer for sensing the pen PN may be omitted, an increase in the thickness and weight of the electronic device 1000 and a decrease in its flexibility due to the addition of a digitizer may not occur. Therefore, the first display panel DP1 and the second display panel DP2 may both be designed to sense the pen PN.

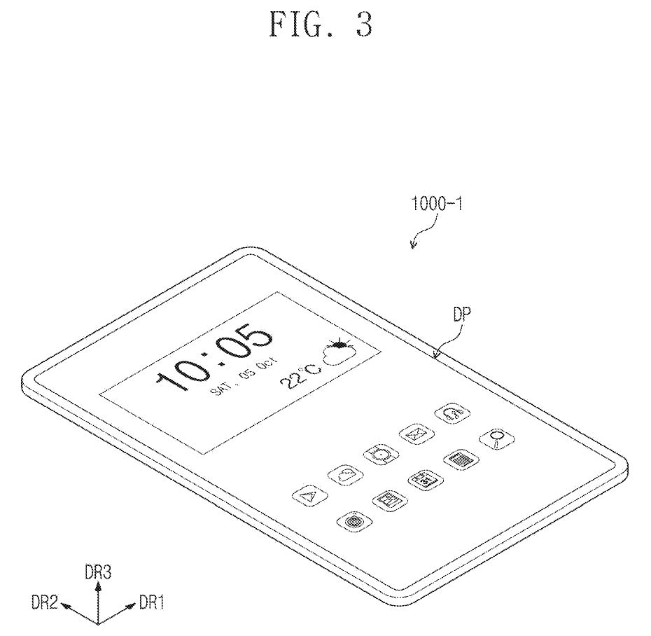

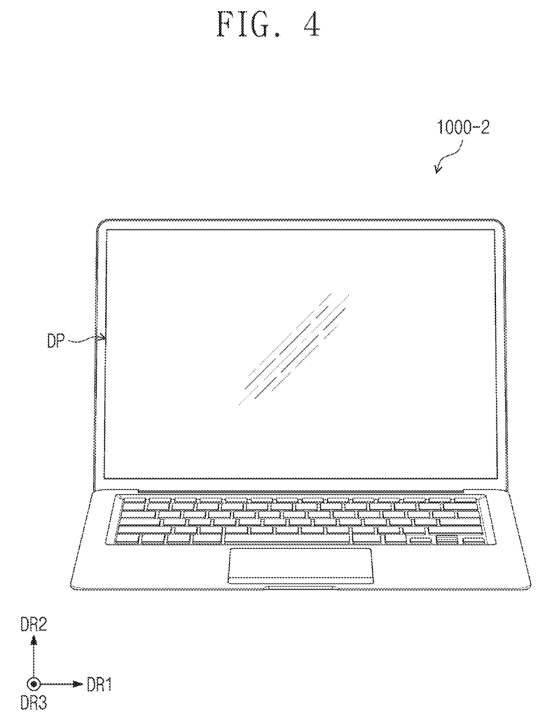

FIG. 3 is a perspective view of an electronic device 1000-1 according to one or more embodiments of the present disclosure. FIG. 4 is a perspective view of an electronic device 1000-2 according to one or more embodiments of the present disclosure.

For example, FIG. 3 illustrates an example in which the electronic device 1000-1 is a bar-type mobile phone, and the electronic device 1000-1 may include a display panel DP. FIG. 4 illustratively shows an example in which the electronic device 1000-2 is a laptop, and the electronic device 1000-2 may include a display panel DP. FIG. 4 is a perspective view of the electronic device 1000-2; however, the coordinate axes included in FIG. 4 are indicated based on the display panel DP within the electronic device 1000-2.

In one or more embodiments of the present disclosure, the display panel DP may sense inputs applied from an external source. The external input may be a user input. The user input may include various types of external inputs, such as a portion of the user's body, a pen PN (see FIG. 2A), light, heat, or pressure.

According to one or more embodiments of the present disclosure, the display panel DP may sense an input by a pen PN even without including a digitizer. Accordingly, because the digitizer for sensing the pen PN may be omitted, an increase in the thickness and weight of the electronic device 1000-1 or 1000-2 due to the addition of a digitizer may not occur.

For example, FIG. 2A illustrates a foldable-type electronic device 1000, and FIG. 3 illustrates a bar-type electronic device 1000-1, altohugh the present disclosure described below is not limited thereto. For example, the following descriptions may be applied to various electronic devices, such as a rollable-type electronic device, a slidable-type electronic device, or a stretchable-type electronic device.

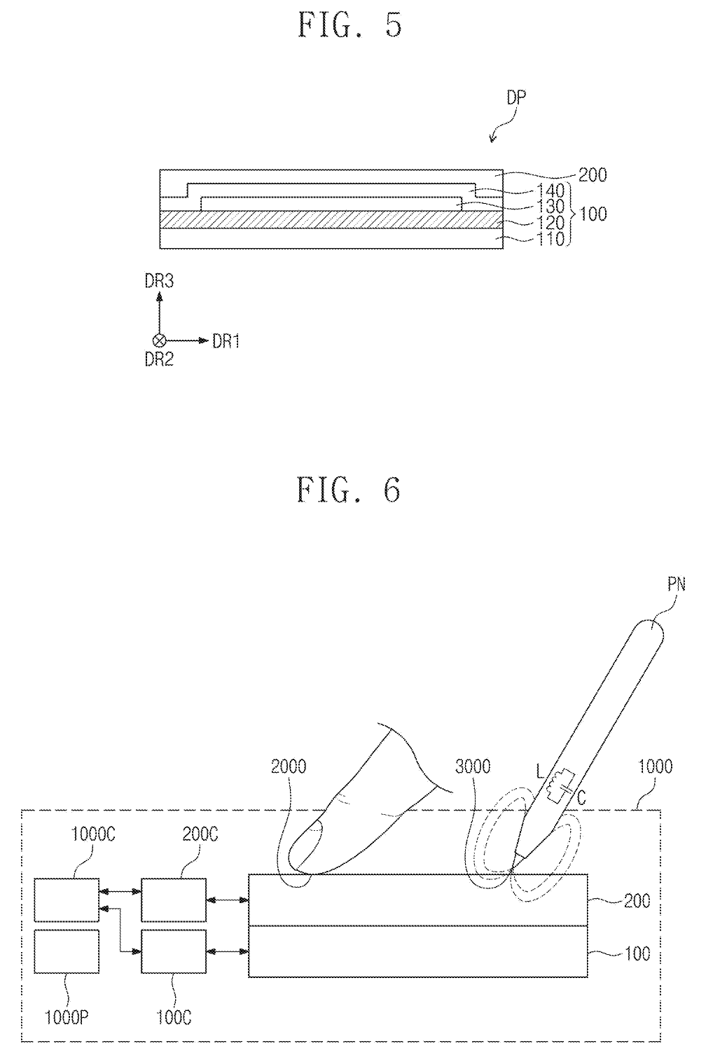

FIG. 5 is a schematic cross-sectional view of the display panel DP according to one or more embodiments of the present disclosure.

Referring to FIG. 5, the display panel DP may include a display layer 100 and a sensor layer 200. An upper functional member may be further located on the sensor layer 200. For example, the upper functional member may include at least one of an anti-reflection layer, a window, or a protective film.

The display layer 100 may be a substantive component that generates an image. The display layer 100 may include a light-emitting display layer. For example, the display layer 100 may include an organic light-emitting display layer, an inorganic light-emitting display layer, an organic-inorganic light-emitting display layer, a quantum dot display layer, a micro-LED display layer, or a nano LED display layer. A display layer 100 may include a base layer 110, a circuit layer 120, a light-emitting element layer 130, and an encapsulation layer 140.

The base layer 110 may be a member that provides a base surface on which the circuit layer 120 is located. The base layer 110 may have a multilayer structure or a single layer structure. The base layer 110 may be a glass substrate, a metal substrate, a silicon substrate, or a polymer substrate, but is not particularly limited thereto.

The circuit layer 120 may be located on the base layer 110. The circuit layer 120 may include an insulating layer, a semiconductor pattern, a conductive pattern, a signal line, and the like. The insulating layer, the semiconductor layer, and the conductive layer may be provided on the base layer 110 through coating and deposition methods, and subsequently, the insulating layer, the semiconductor layer, and the conductive layer may be selectively patterned through photolithography processes performed multiple times.

The light-emitting element layer 130 may be located on the circuit layer 120. The light-emitting element layer 130 may include a light-emitting element. For example, the light-emitting element layer 130 may include an organic light-emitting material, an inorganic light-emitting material, an organic-inorganic light-emitting material, a quantum dot, a quantum rod, a micro-LED, a nano LED, or the like.

The encapsulation layer 140 may be located on the light-emitting element layer 130. The encapsulation layer 140 may protect the light-emitting element layer 130 from foreign substances, such as moisture, oxygen, and dust particles.

A sensor layer 200 may be located on the display layer 100. The sensor layer 200 may sense an external input applied from an external source. The sensor layer 200 may be an integrated sensor that is continuously provided during the manufacturing process of the display layer 100, or an external sensor attached to the display layer 100. The sensor layer 200 may be referred to as a sensor, an input-sensing layer, an input-sensing panel, or an electronic device for input coordinate sensing.

According to one or more embodiments of the present disclosure, the sensor layer 200 may sense both an input from a passive-type input means, such as a user's body, and an input from an input device that generates a magnetic field of a corresponding resonance frequency. The input device may be referred to as a pen, an input pen, a magnetic pen, a stylus pen, or an electromagnetic resonance pen.

FIG. 6 is a diagram for explaining the operation of the electronic device 1000 according to one or more embodiments of the present disclosure.

Referring to FIG. 6, the electronic device 1000 may include a display layer 100, a sensor layer 200, a display driver 100C, a sensor driver 200C, a main driver 1000C, and a power circuit 1000P.

The sensor layer 200 may sense a first input 2000 or a second input 3000 applied from an external source. The first input 2000 and the second input 3000 may each be an input means capable of providing a change in capacitance of the sensor layer 200 or an input means capable of inducing an eddy current in the sensor layer 200. For example, the first input 2000 may be an input from a passive-type input means, such as a user's body. The second input 3000 may be an input by a pen PN or an RFIC (radio-frequency integrated circuit) tag. For example, the pen PN may be a passive-type pen or an active-type pen.

In one or more embodiments of the present disclosure, the pen PN may be a device that generates a magnetic field of a corresponding resonance frequency. The pen PN may be configured to transmit an output signal based on an electromagnetic resonance method. The pen PN may be referred to as an input device, an input pen, a magnetic pen, a stylus pen, or an electromagnetic resonance pen.

The pen PN may include an RLC resonance circuit, and the RLC resonance circuit may include an inductor L and a capacitor C. In one or more embodiments of the present disclosure, the RLC resonance circuit may be a variable resonance circuit that varies the resonance frequency. In this case, the inductor L may be a variable inductor and/or the capacitor C may be a variable capacitor, but it is not particularly limited thereto.

The inductor L may generate a current due to a magnetic field generated in the electronic device 1000, for example, in the sensor layer 200. However, it is not particularly limited thereto. For example, when the pen PN operates in an active type, the pen PN may generate a current even without receiving a magnetic field from an external source. The generated current may be delivered to the capacitor C. The capacitor C may charge the current input from the inductor L and discharge the charged current back to the inductor L. Subsequently, the inductor L may emit a magnetic field of a resonance frequency. The magnetic field emitted by the pen PN may induce a current in the sensor layer 200, and the induced current may be transmitted to the sensor driver 200C as a received signal (or a sensing signal or a signal).

The main driver 1000C may control the overall operation of the electronic device 1000. For example, the main driver 1000C may control the operation of the display driver 100C and the sensor driver 200C. The main driver 1000C may include at least one microprocessor and may further include a graphics controller. The main driver 1000C may be referred to as an application processor, a central processing unit, or a main processor.

The display driver 100C may drive the display layer 100. The display driver 100C may receive image data and a control signal from the main driver 1000C. The control signal may include various signals. For example, the control signal may include an input vertical synchronization signal, an input horizontal synchronization signal, a main clock signal, and a data enable signal.

The sensor driver 200C may drive the sensor layer 200. The sensor driver 200C may receive image data and the control signal from the main driver 1000C. The control signals may include a clock signal of the sensor driver 200C. Additionally, the control signals may further include a mode determination signal that determines the driving mode of the sensor driver 200C and the sensor layer 200.

The sensor driver 200C may be implemented as an integrated circuit IC and may be electrically connected to the sensor layer 200. For example, the sensor driver 200C may be directly mounted on a corresponding area of the display panel or mounted on a separate printed circuit board using a chip-on-film COF method to be electrically connected to the sensor layer 200.

The sensor driver 200C and the sensor layer 200 may selectively operate in a first mode or a second mode. For example, the first mode may be a mode for sensing a touch input, such as the first input 2000. The second mode may be a mode for sensing a pen PN input, such as the second input 3000. The first mode may be referred to as a touch-sensing mode, and the second mode may be referred to as a pen-sensing mode.

The transition between the first mode and the second mode may be performed in various ways. For example, the sensor driver 200C and the sensor layer 200 may be time-divisionally driven in the first mode and the second mode to sense the first input 2000 and the second input 3000. Alternatively, the transition between the first mode and the second mode may occur based on a user's selection or a corresponding action (or input), or either mode may be activated, deactivated, or switched to the other mode depending on the activation state of a corresponding application. Alternatively, while the sensor driver 200C and the sensor layer 200 alternately operate in the first mode and the second mode, when the first input 2000 is sensed, the first mode may be maintained, or when the second input 3000 is sensed, the second mode may be maintained.

The sensor driver 200C may calculate coordinate information of the input based on a signal received from the sensor layer 200 and may provide a coordinate signal with the coordinate information to the main driver 1000C. The main driver 1000C may execute an operation corresponding to a user input based on the coordinate signal. For example, the main driver 1000C may operate the display driver 100C to display a new application image on the display layer 100.

The power circuit 1000P may include a power management integrated circuit PMIC. The power circuit 1000P may generate a plurality of driving voltages for driving the display layer 100, the sensor layer 200, the display driver 100C, and the sensor driver 200C. For example, the plurality of driving voltages may include a gate high voltage, a gate low voltage, a first driving voltage, a second driving voltage, and an initialization voltage, but is not particularly limited thereto.

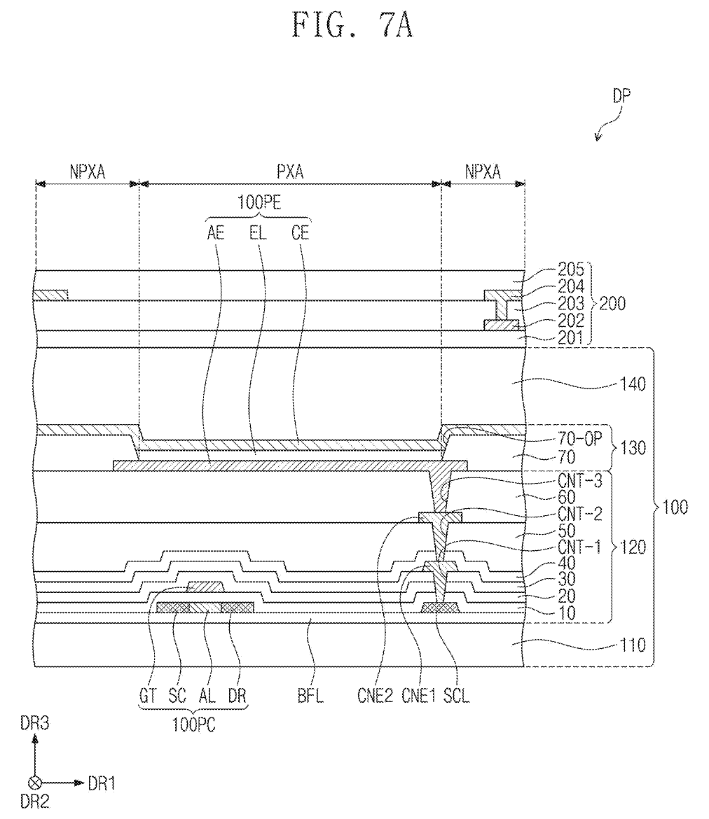

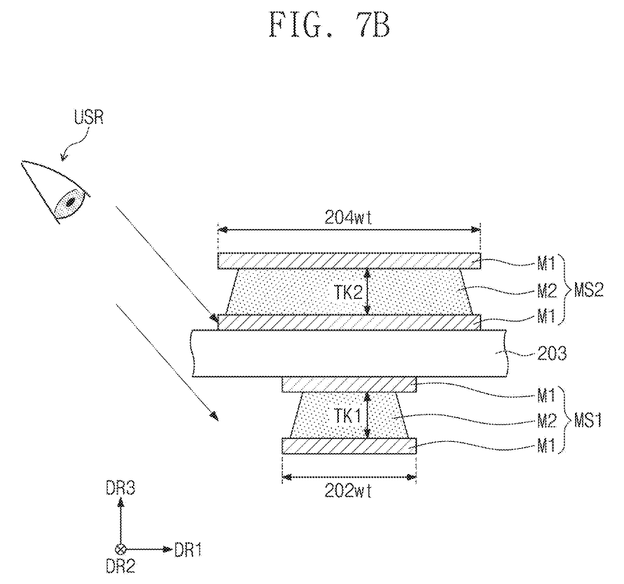

FIG. 7A is a cross-sectional view of the display panel DP according to one or more embodiments of the present disclosure.

Referring to FIG. 7A, at least one buffer layer BFL may be located on a top surface of the base layer 110. The buffer layer BFL may enhance adhesive force between the base layer 110 and a semiconductor pattern. The buffer layer BFL may be provided in a multilayer structure. Alternatively, the display layer 100 may further include a barrier layer. The buffer layer BFL may include at least one of silicon oxide, silicon nitride, or silicon oxynitride. For example, the buffer layer BFL may include a structure in which silicon oxide layers and silicon nitride layers are alternately stacked.

Semiconductor patterns SC, AL, DR and SCL may be located on the buffer layer BFL. The semiconductor patterns SC, AL, DR and SCL may include polysilicon. However, it is not limited thereto, and the semiconductor patterns SC, AL, DR and SCL may also include amorphous silicon, low-temperature polycrystalline silicon, or an oxide semiconductor.

FIG. 7A merely illustrates a portion of the semiconductor patterns SC, AL, DR, and SCL, and additional semiconductor patterns may be located in other areas. The semiconductor patterns SC, AL, DR and SCL may be arranged in a corresponding pattern across the pixels. The electrical properties of the semiconductor patterns SC, AL, DR and SCL may vary depending on whether doping is applied. The semiconductor patterns SC, AL, DR and SCL may include first regions SC, DR and SCL having high conductivity and a second region AL having low conductivity. The first regions SC, DR and SCL may be doped with an N-type dopant or a P-type dopant. A P-type transistor may include a doped region doped with a P-type dopant, and an N-type transistor may include a doped region doped with an N-type dopant. The second region AL may be a non-doped region or a region doped at a lower concentration compared to the first regions SC, DR and SCL.

The conductivity of the first regions SC, DR and SCL may be greater than that of the second region AL, and may function as an electrode or a signal line. The second region AL may substantially correspond to an active region AL (or channel) of a transistor 100PC. In other words, a portion AL of the semiconductor patterns SC, AL, DR, and SCL may serve as the active region AL of the transistor 100PC, another portions SC and DR may serve as the source region SC or the drain region DR of the transistor 100PC, and yet another portion SCL may serve as a connection electrode or a connection signal line SCL.

Each pixel may have an equivalent circuit including a plurality of transistors, at least one capacitor, and at least one light-emitting element, and the equivalent circuit of the pixel may be modified into various shapes. For example, FIG. 7A illustrates one transistor 100PC and one light-emitting element 100PE included in a pixel.

The source region SC, active region AL, and drain region DR of the transistor 100PC may be provided from the semiconductor patterns SC, AL, DR, and SCL. The source region SC and the drain region DR may extend in opposite directions from the active region AL in the cross-section. FIG. 7A illustrates a portion of the connection signal line SCL provided from the semiconductor patterns SC, AL, DR and SCL. In one or more embodiments, the connection signal line SCL may be connected to the drain region DR of the transistor 100PC in the planar view.

A first insulating layer 10 may be located on the buffer layer BFL (as used herein, “located on” may mean “above”). The first insulating layer 10 may commonly overlap across a plurality of pixels and may cover the semiconductor patterns SC, AL, DR and SCL. The first insulating layer 10 may be an inorganic layer and/or an organic layer and may have a single-layer or multi-layer structure. The first insulating layer 10 may include at least one of aluminum oxide, titanium oxide, silicon oxide, silicon nitride, silicon oxynitride, zirconium oxide, or hafnium oxide. The first insulating layer 10 may be a single-layer silicon oxide layer. In addition to the first insulating layer 10, the insulating layer of a circuit layer 120, which will be described later, may be inorganic layers and/or organic layers and may have a single-layer or multi-layer structure. The inorganic layer may include at least one of the materials described above, and the present disclosure is not limited thereto.

A gate GT of the transistor 100PC may be located on the first insulating layer 10. The gate GT may be a portion of a metal pattern. The gate GT may overlap the active region AL. During a process for doping or reduction the semiconductor patterns SC, AL, DR, and SCL, the gate GT may function as a mask.

A second insulating layer 20 may be located on the first insulating layer 10 and may cover the gate GT. The second insulating layer 20 may commonly overlap the pixels. The second insulating layer 20 may be an inorganic layer and/or an organic layer and may have a single-layer or multi-layer structure. The second insulating layer 20 may include at least one of silicon oxide, silicon nitride, or silicon oxynitride. The second insulating layer 20 may have a multi-layer structure including a silicon oxide layer and a silicon nitride layer.

A third insulating layer 30 may be located on the second insulating layer 20. The third insulating layer 30 may have a single- or multi-layer structure. For example, the third insulating layer 30 may have a multi-layer structure including a silicon oxide layer and a silicon nitride layer.

A first connection electrode CNE1 may be located on the third insulating layer 30. The first connection electrode CNE1 may be connected to a connection signal line SCL through a contact hole CNT-1 penetrating through the first, second, and third insulating layers 10, 20, and 30.

A fourth insulating layer 40 may be located on the third insulating layer 30. The fourth insulating layer 40 may be a single-layer silicon oxide layer. A fifth insulating layer 50 may be located on the fourth insulating layer 40. The fifth insulating layer 50 may be an organic layer.

A second connection electrode CNE2 may be located on the fifth insulating layer 50. The second connection electrode CNE2 may be connected to the first connection electrode CNE1 through a contact hole CNT-2 passing through the fourth insulation layer 40 and the fifth insulation layer 50.

A sixth insulating layer 60 may be located on the fifth insulating layer 50 and cover the second connection electrode CNE2. The sixth insulating layer 60 may be an organic layer.

The light-emitting element layer 130 may be located on the circuit layer 120. The light-emitting element layer 130 may include a light-emitting element 100PE. For example, the light-emitting element layer 130 may include an organic light-emitting material, an inorganic light-emitting material, an organic-inorganic light-emitting material, a quantum dot, a quantum rod, a micro LED, a nano LED, or the like. Hereinafter, the light-emitting element 100PE will be described with an organic light-emitting element as an example, but is not particularly limited thereto.

The light-emitting element 100PE may include a first electrode AE, an emission layer EL, and a second electrode CE.

The first electrode AE may be located on a sixth insulating layer 60. The first electrode AE may be connected to the second connection electrode CNE2 through a contact hole CNT-3 penetrating the sixth insulating layer 60.

A pixel-defining layer 70 may be located on the sixth insulating layer 60 and may cover a portion of the first electrode AE. An opening portion 70-OP may be defined in a pixel-defining layer 70. The opening portion 70-OP of the pixel-defining layer 70 exposes at least a portion of the first electrode AE.

The first display area DA1-F (see FIG. 2A) may include an emission area PXA and a non-emission area NPXA adjacent to the emission area PXA. A non-emission area NPXA may surround the emission area PXA. The emission area PXA is defined corresponding to a partial area of the first electrode AE exposed through the opening 70-OP.

The emission layer EL may be located on the first electrode AE. The emission layer EL may be located in an area corresponding to the opening 70-OP. For example, FIG. 7A illustratively shows an example in which the emission layer EL is located in the opening 70-OP, but it is not particularly limited thereto. For example, the emission layer EL may extend to cover a side surface of the pixel-defining layer 70 that defines the opening 70-OP, and a portion of a top surface of the pixel-defining layer 70.

In one or more embodiments of the present disclosure, the emission layer EL may be separately included in each pixel. When the emission layer EL is separately provided within each pixel, each emission layer EL may emit light of at least one of blue, red, or green colors. However, the emission layer EL is not limited thereto, and the emission layer EL may have an integrated shape and may be commonly included in a plurality of pixels. In this case, the emission layer EL may provide blue light or white light.

The second electrode CE may be located on the emission layer EL. The second electrode CE may have an integrated shape, and may be commonly included in a plurality of pixels.

In one or more embodiments of the present disclosure, a hole control layer may be located between the first electrode AE and the emission layer EL. The hole control layer may be located in common in the emission area PXA and the non-emission area NPXA. The hole control layer may include a hole transport layer and may further include a hole injection layer. An electron control layer may be located between the light-emitting layer EL and the second electrode CE. The electron control layer may include an electron transport layer and may further include an electron injection layer. The hole control layer and the electron control layer may be commonly located on a plurality of pixels using an open mask or an inkjet process.

The encapsulation layer 140 may be located on the light-emitting element layer 130. The encapsulation layer 140 may include an inorganic layer, an organic layer, and an inorganic layer, which are stacked in this order, but layers constituting the encapsulation layer 140 are not limited thereto. The inorganic layers may protect the light-emitting element layer 130 from moisture and oxygen, and the organic layer may protect the light-emitting element layer 130 from foreign substances, such as dust particles. The inorganic layers may include a silicon nitride layer, a silicon oxynitride layer, a silicon oxide layer, a titanium oxide layer, or an aluminum oxide layer. The organic layer may include an acrylic-based organic layer, but the present disclosure is not limited thereto.

The sensor layer 200 may include a base layer 201, a first conductive layer 202, an intermediate insulating layer 203, a second conductive layer 204, and a cover insulating layer 205.

The base layer 201 may be an inorganic layer including at least one of silicon nitride, silicon oxynitride, or silicon oxide. Alternatively, the base layer 201 may be an organic layer including epoxy resin, acrylic resin, or imide-based resin. The base layer 201 may have a single-layer structure or a multilayer structure laminated along the third direction DR3. In one or more embodiments of the present disclosure, the sensor layer 200 may not include the base layer 201.

Each of the first conductive layer 202 and the second conductive layer 204 may have a single layer structure or a multilayer structure in which layers are stacked in a third direction axis DR3.

Each of the first conductive layer 202 and second conductive layer 204 in a single-layer structure may include a metal layer or a transparent conductive layer. The metal layer may include molybdenum, silver, titanium, copper, aluminum, or an alloy thereof. The transparent conductive layer may include a transparent conductive oxide, such as indium tin oxide (ITO), indium zinc oxide (IZO), zinc oxide (ZnO), or indium zinc tin oxide (IZTO). Additionally, the transparent conductive layer may include a conductive polymer, such as poly(3,4-ethylenedioxythiophene) PEDOT, metal nanowires, or graphene.

Each of the first conductive layer 202 and second conductive layer 204 in a multilayer structure may include metal layers. The metal layers may have, for example, a three-layer structure of titanium/aluminum/titanium. The conductive layer having a multilayer structure may include at least one metal layer and at least one transparent conductive layer.

In one or more embodiments of the present disclosure, the first conductive layer 202 may have a thickness greater than that of the second conductive layer 204. When the thickness of the first conductive layer 202 is greater than that of the second conductive layer 204, the resistance of the components included in the first conductive layer 202, such as electrodes, patterns, or bridge patterns, may be reduced. Additionally, because the first conductive layer 202 is positioned below the second conductive layer 204, even if the thickness of the first conductive layer 202 is increased, the probability of visual recognition of the components included in the first conductive layer 202 due to external light reflection may be lower than that of the second conductive layer 204.

At least one of the intermediate insulating layer 203 or cover insulating layer 205 may include an inorganic film. The inorganic film may include at least one of aluminum oxide, titanium oxide, silicon oxide, silicon nitride, silicon oxynitride, zirconium oxide, or hafnium oxide.

At least one of the intermediate insulating layer 203 or cover insulating layer 205 may include an organic film. The organic film may include at least one of acrylic resin, methacrylic resin, polyisoprene, vinyl resin, epoxy resin, urethane resin, cellulose resin, siloxane resin, polyimide resin, polyamide resin, or perylene resin.

Previously, the sensor layer 200 was described as including the first conductive layer 202 and the second conductive layer 204, meaning a total of two conductive layers as an example, but it is not particularly limited thereto. For example, the sensor layer 200 may include three or more conductive layers.

FIG. 7B is a cross-sectional view illustrating a portion of the sensor layer 200 (see FIG. 7A) according to one or more embodiments of the present disclosure.

Referring to FIGS. 7A and 7B, a second width 204wt of a second mesh line MS2 included in the second conductive layer 204 may be equal to or greater than a first width 202wt of a first mesh line MS1 included in the first conductive layer 202. When the user USR views the first mesh line MS1 and the second mesh line MS2 from the side, because the first mesh line MS1 has a width that is less than that of the second mesh line MS2, the probability of the first mesh line MS1 being visually recognized by the user USR may be reduced.

Each of the first mesh line MS1 and the second mesh line MS2 may include the first metal layers M1 and a second metal layer M2 located between the first metal layers M1. For example, the first metal layers M1 may include titanium (Ti), and the second metal layer M2 may include aluminum (Al). However, this is merely an example and is not particularly limited thereto.

In one or more embodiments of the present disclosure, a first thickness TK1 of the second metal layer M2 of the first mesh line MS1, and a second thickness TK2 of the second metal layer M2 of the second mesh line MS2, may be substantially the same, but it is not particularly limited thereto. For example, the first thickness TK1 may be greater than the second thickness TK2. Alternatively, the second thickness TK2 may be greater than the first thickness TK1. In one or more embodiments of the present disclosure, each of the first thickness TK1 and the second thickness TK2 may be about 1000 Å or more, and, for example, may be about 6000 Å or more.

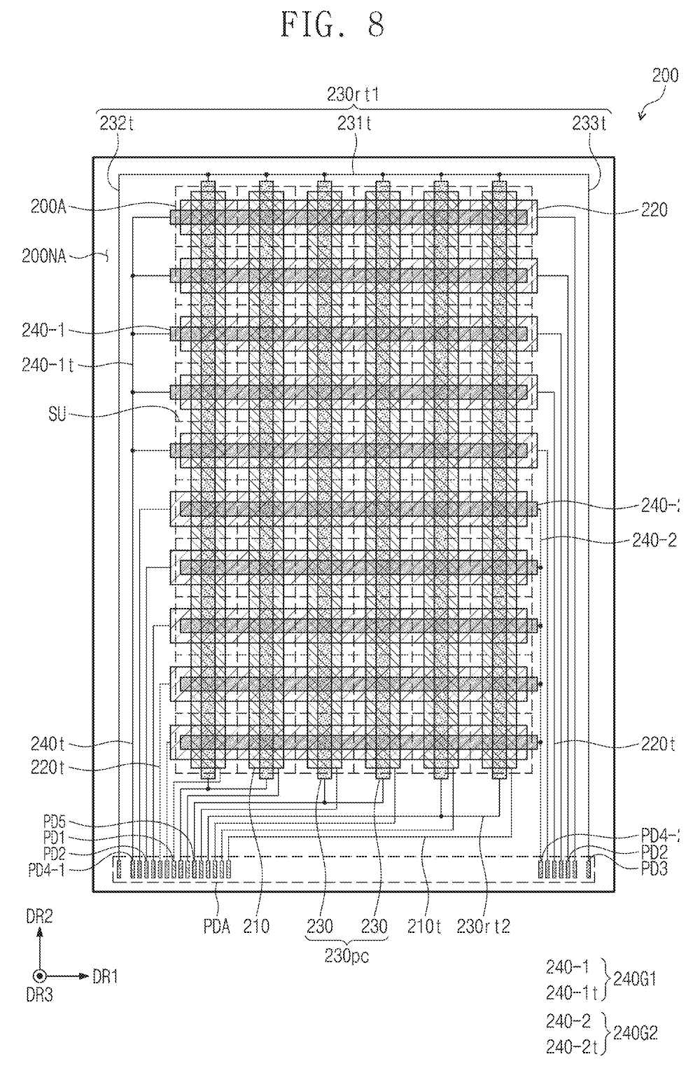

FIG. 8 is a plan view of the sensor layer 200 according to one or more embodiments of the present disclosure.

Referring to FIG. 8, a sensing area 200A, and a peripheral area 200NA adjacent to the sensing area 200A, may be defined in the sensor layer 200.

The sensor layer 200 may include a plurality of first electrodes 210, a plurality of second electrodes 220, a plurality of third electrodes 230, a first auxiliary electrode group 240G1, and a second auxiliary electrode group 240G2. In one or more embodiments of the present disclosure, the sensor layer 200 may not include the third electrodes 230.

Each of the first electrodes 210 may cross with the second electrodes 220. Each of the first electrodes 210 may extend along the second direction DR2, and the first electrodes 210 may be arranged spaced apart from each other in the first direction DR1. Each of the second electrodes 220 may extend along the first direction DR1, and the second electrodes 220 may be arranged spaced apart from each other in the second direction DR2. A sensing unit SU of the sensor layer 200 may be an area in which one first electrode 210 and one second electrode 220 cross.

FIG. 8 illustrates six first electrodes 210, ten second electrodes 220, and sixty sensing units SU, but the numbers of the first electrodes 210 and the second electrodes 220 are not limited thereto.

Each of the third electrodes 230 may extend along the second direction DR2, and the third electrodes 230 may be arranged spaced apart from each other in the first direction DR1. One third electrode 230 may at least partially overlap with one first electrode 210. According to one or more embodiments of the present disclosure, the capacitance (or coupling capacitance) between the first electrode 210 and the third electrode 230 may be controlled through adjustment of an overlapping surface area between one first electrode 210 and one third electrode 230.

In one or more embodiments of the present disclosure, at least a part of the third electrodes 230 may be connected in parallel. For example, in FIG. 8, two third electrodes 230 are connected in parallel to provide a first electrode group 230pc as an example, and three first electrode groups 230pc may be arranged along the first direction DR1. However, the number of third electrodes 230 constituting the first electrode group 230pc is not limited thereto. For example, one first electrode group 230pc may include only one third electrode 230 or may include three or more third electrodes 230.

As the number of third electrodes 230 included in the first electrode group 230pc and connected in parallel increases, the resistance of the first electrode group 230pc may decrease, thereby improving power efficiency and enhancing sensing sensitivity. Conversely, as the number of third electrodes 230 included in the first electrode group 230pc decreases, the loop coil pattern made by using the first electrode group 230pc may be implemented in a more diverse manner.

The first auxiliary electrode group 240G1 may include a plurality of first auxiliary electrodes 240-1 arranged along the second direction DR2, and a first auxiliary trace line 240-1t electrically connected to the first auxiliary electrodes 240-1. The second auxiliary electrode group 240G2 may include a plurality of second auxiliary electrodes 240-2 arranged along the second direction DR2, and a second auxiliary trace line 240-2t electrically connected to the second auxiliary electrodes 240-2.

The first and second auxiliary electrodes 240-1 and 240-2 may at least partially overlap with the second electrodes 220 in a one-to-one correspondence. According to one or more embodiments of the present disclosure, the capacitance (or coupling capacitance) between the second electrode 220 and the auxiliary electrode 240-1 or 240-2 may be controlled through adjustment of the overlapping surface area between one second electrode 220 and one auxiliary electrode 240-1 or 240-2.

The sensor layer 200 may further include a plurality of first trace lines 210t arranged in the peripheral area 200NA, a plurality of first pads PD1 connected to the first trace lines 210t in a one-to-one correspondence, a plurality of second trace lines 220t, and a plurality of second pads PD2 connected to the second trace lines 220t in a one-to-one correspondence. The first trace lines 210t may be electrically connected to the first electrodes 210 in a one-to-one correspondence. The second trace lines 220t may be electrically connected to the second electrodes 220 in a one-to-one correspondence.

The sensor layer 200 may further include a first loop trace line 230rt1 arranged in the peripheral area 200NA, a plurality of third pads PD3 connected to ends (e.g., one and the other ends, or first and second ends) of the first loop trace line 230rt1, a (4-1)-th pad PD4-1 connected to the first auxiliary trace line 240-1t, a (4-2)-th pad PD4-2 connected to the second auxiliary trace line 240-2t, second loop trace lines 230rt2, and fifth pads PD5 connected to the second loop trace lines 230rt2 in a one-to-one correspondence.

The first loop trace line 230rt1 may be electrically connected to the third electrodes 230. In one or more embodiments of the present disclosure, the first loop trace line 230rt1 may be electrically connected to the entire third electrodes 230. The first loop trace line 230rt1 may extend along the first direction DR1 and may include a first line portion 231t electrically connected to the third electrodes 230, a second line portion 232t extending along the second direction DR2 from a first end of the first line portion 231t, and a third line portion 233t extending along the second direction DR2 from a second end of the first line portion 231t.

In one or more embodiments of the present disclosure, each of the second line portion 232t and the third line portion 233t may have resistance, which is substantially the same as one of the third electrodes 230. Accordingly, the second line portion 232t and the third line portion 233t may serve as the third electrodes 230, achieving the same effect as if the third electrodes 230 were also arranged in the peripheral area 200NA. For example, either the second line portion 232t or third line portion 233t, together with one of the third electrodes 230, may constitute a coil. Thus, a pen located in an area adjacent to the peripheral area 200NA may be sufficiently charged by a loop including the second line portion 232t or the third line portion 233t.

In one or more embodiments of the present disclosure, the width of the second line portion 232t and the third line portion 233t in the first direction DR1 may be adjusted to control resistance of the second line portion 232t and resistance of the third line portion 233t. However, this is merely an example, and the first to third line portions 231t, 232t, and 233t may have substantially the same width.

The second loop trace lines 230rt2 may be connected to the first electrode groups 230pc in a one-to-one correspondence. That is, the number of second loop trace lines 230rt2 may correspond to the number of first electrode groups 230pc. In FIG. 8, three second loop trace lines 230rt2 and three first electrode groups 230pc are illustrated.

In one or more embodiments of the present disclosure, the second loop trace lines 230rt2 and the fifth pads PD5 may be omitted, and a charging operation mode for charging a pen may also be omitted. In this case, the sensor layer 200 may sense input by an active-type pen capable of emitting a magnetic field even if the sensor layer 200 does not provide a magnetic field.

The first auxiliary trace line 240-1t and the second auxiliary trace line 240-2t may be arranged in the peripheral area 200NA, and may be spaced apart from each other with the sensing area 200A in between. On the peripheral area 200NA, a pad area PDA in which the first pads PD1, the second pads PD2, the third pads PD3, the (4-1)-th pad PD4-1, the (4-2)-th pad PD4-2, and the fifth pad PD5 are arranged, may be defined. The second auxiliary electrodes 240-2 may be located between the first auxiliary electrodes 240-1 and the pad area PDA (e.g., along the second direction DR2).

The mutual capacitance between the first electrode 210 and the second electrode 220 may vary due to the first auxiliary electrode group 240G1 and the second auxiliary electrode group 240G2. For example, the mutual capacitance may vary due to coupling between the first auxiliary electrode group 240G1 and the first electrode 210, and due to coupling between the second auxiliary electrode group 240G2 and the first electrode 210. The deviation in the amount of change in the mutual capacitance may increase as the difference in resistance between the first auxiliary electrode group 240G1 and the second auxiliary electrode group 240G2 increases. Additionally, the deviation in the amount of change in the mutual capacitance may be further exacerbated by rapid temperature changes, which may cause touch malfunctions.

According to one or more embodiments of the present disclosure, the first auxiliary electrode group 240G1 may have the same impedance as the second auxiliary electrode group 240G2. In this case, the deviation in the amount of change in the mutual capacitance caused by the first auxiliary electrode group 240G1 and the second auxiliary electrode group 240G2 may be reduced or minimized. As the deviation decreases, the probability of touch malfunctions may be reduced or eliminated. As a result, the touch reliability of the sensor layer 200 may be improved.

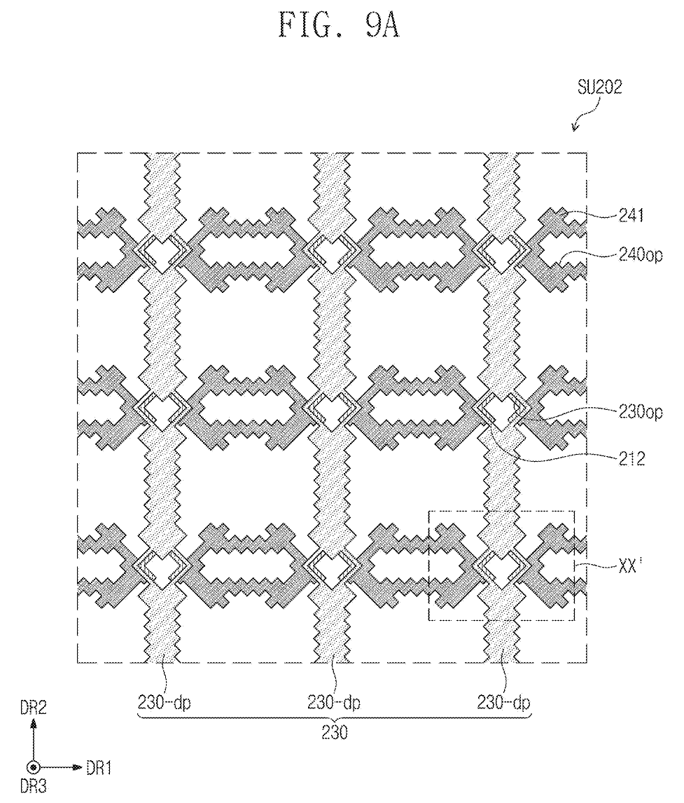

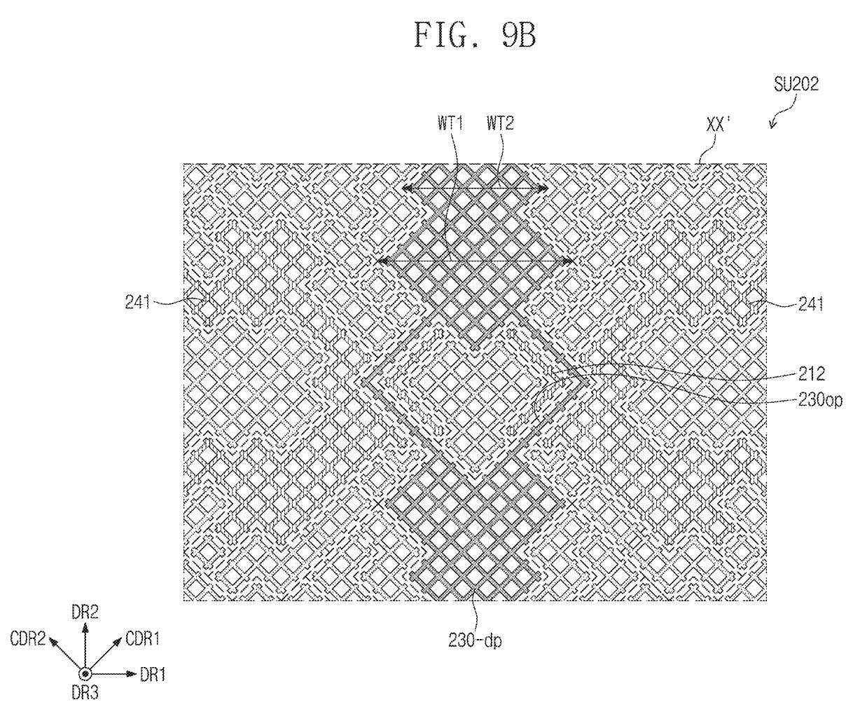

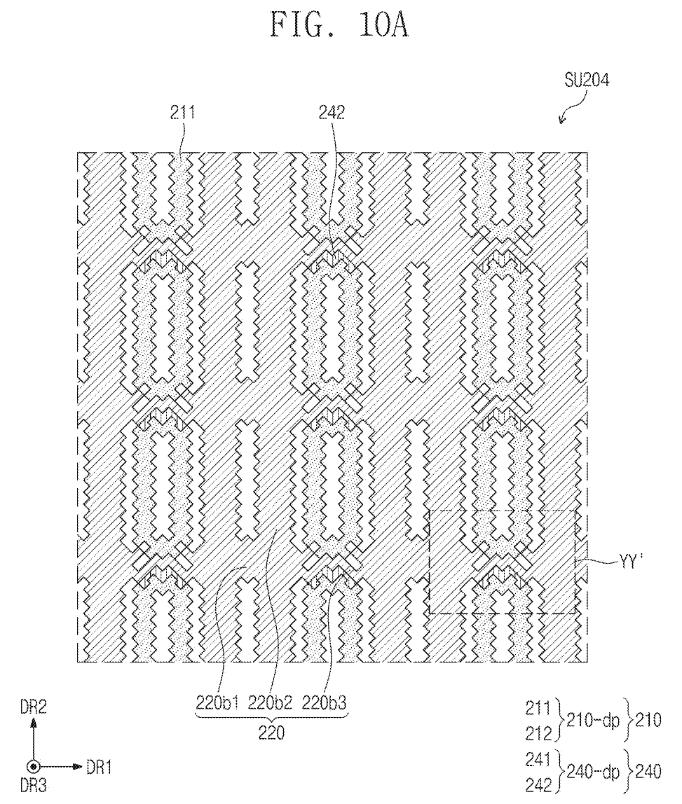

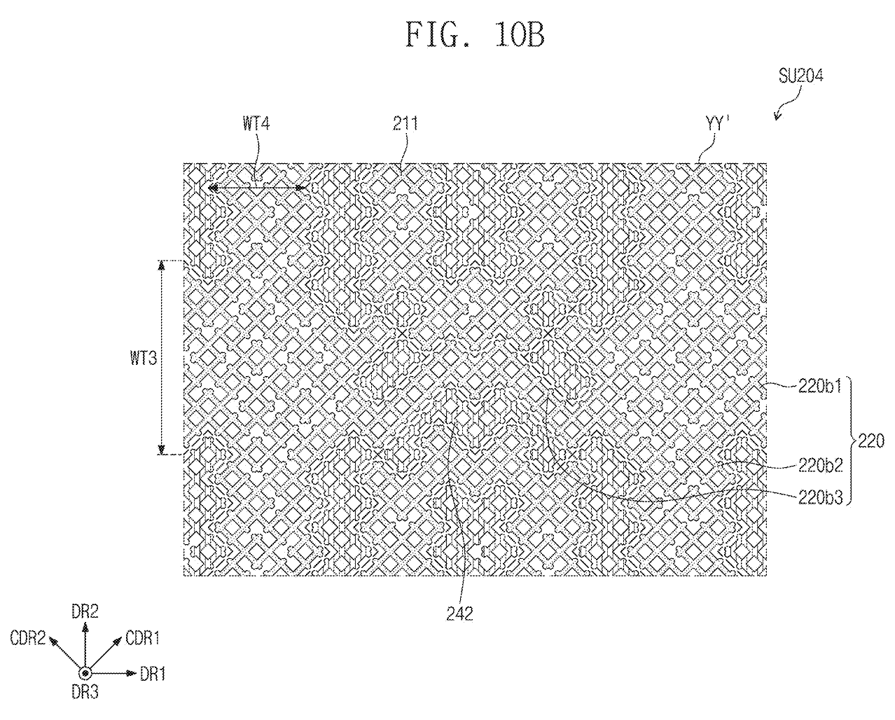

FIG. 9A is a plan view illustrating a first conductive layer SU202 of the sensing unit SU (see FIG. 8) according to one or more embodiments of the present disclosure. FIG. 9B is an enlarged plan view of an XX' area shown in FIG. 9A. FIG. 10A is a plan view illustrating a second conductive layer SU204 of the sensing unit SU (see FIG. 8) according to one or more embodiments of the present disclosure. FIG. 10B is an enlarged view of an area YY’ of FIG. 10A.

In FIGS. 9A and 10A, a shape of the mesh structure is not illustrated, and the boundaries of each component are simply illustrated by lines. That is, the lines shown in FIGS. 9A and 10A may correspond to cutting lines obtained by cutting the mesh structure illustrated in FIGS. 9B and 10B, and in FIGS. 9B and 10B, the cutting lines are illustrated by dotted lines.

The shape of the sensing unit SU illustrated in FIGS. 8, 9A, 9B, 10A and 10B, is merely an example, and the present disclosure is not limited thereto. The shape of the sensing unit SU may be variously modified.

Referring to FIGS. 8, 9A, 9B, 10A and 10B, the first electrode 210 may include a plurality of first divided electrodes 210-dp spaced apart from each other in the first direction DR1. The first divided electrodes 210-dp may be connected to a single first trace line 210t. Each of the first divided electrodes 210-dp may include a plurality of first patterns 211, and a plurality of first bridge patterns 212 electrically connected to the first patterns 211. The first patterns 211, spaced apart from each other and arranged in the second direction DR2, may be electrically connected by the first bridge patterns 212. Accordingly, each of the first divided electrodes 210-dp may extend in the second direction DR2, and the first divided electrodes 210-dp may be spaced apart in the first direction DR1.

The third electrode 230 may include a plurality of second divided electrodes 230-dp spaced apart from each other in the first direction DR1. Each of the second divided electrodes 230-dp may extend in the second direction DR2. The second divided electrodes 230-dp may be spaced apart from each other in the first direction DR1.

When viewed from the third direction DR3, the second divided electrodes 230-dp may overlap the first divided electrodes 210-dp in a one-to-one correspondence. Herein, the term "overlapping" may also include a case in which, for example, at least a portion of one first divided electrode 210-dp and at least a portion of one second divided electrode 230-dp overlap.

In FIGS. 9A and 10A, an example is illustrated in which one sensing unit SU includes three first divided electrodes 210-dp and three second divided electrodes 230-dp, but it is not particularly limited thereto. For example, the number of first divided electrodes 210-dp and second divided electrodes 230-dp included in single sensing unit SU may be one, two, or four or more. Each of the first divided electrodes 210-dp and second divided electrodes 230-dp may correspond to a signal transmission path or a resistance path through which a signal is transmitted.

Referring to FIGS. 8 and 9A, one second loop trace line 230rt2 may be electrically connected to one first electrode group 230pc. One first electrode group 230pc may include two third electrodes 230. In this case, one second loop trace line 230rt2 may be electrically connected to six second divided electrodes 230-dp. As a result, the extent to which the number of pads increases in the sensor layer 200 may be reduced.

Compared to a case in which the first electrode 210 in one sensing unit SU is not divided and has a single shape, when the first electrode 210 in one sensing unit SU includes the first divided electrodes 210-dp, the first divided electrodes 210-dp may be relatively evenly distributed within one sensing unit SU. In this case, signals may be evenly provided or detected within one sensing unit SU.

Additionally, compared to a case where the first electrode 210 in one sensing unit SU is not divided, when the first electrode 210 in one sensing unit SU includes the first divided electrodes 210-dp, the number of first bridge patterns 212 in one sensing unit SU may increase. In FIG. 9A, when two first bridge patterns 212 connected to the same two first patterns 211 are regarded as one pair, for example, nine pairs of first bridge patterns 212 are illustrated. That is, a total of eighteen first bridge patterns 212 are illustrated.

For example, an increase in the number of first bridge patterns 212 arranged in the first direction DR1, which crosses the second direction DR2 as the extension direction of the first electrode 210, may correspond to an increase in signal paths. Therefore, as the number of signal paths increases, the resistance of the first electrode 210 may decrease. As a result, the sensing sensitivity of the sensor layer 200 may be improved.

Additionally, as the shape of each first divided electrode 210-dp becomes closer to a bar extending in the second direction DR2, the resistance path may be shortened. Accordingly, as the resistance path becomes shorter, and as the number of resistance paths connected in parallel within one first electrode 210 increases, the resistance of the first electrode 210 may decrease. As a result, the sensing sensitivity of the sensor layer 200 may be improved.

Moreover, as the shape of each first divided electrode 210-dp becomes closer to a bar extending in the second direction DR2, a ratio of the surface area available for pattern design within the entire surface area of one sensing unit SU may increase. Therefore, the degree of freedom in pattern design may be improved.

According to one or more embodiments of the present disclosure, the degree of freedom in pattern design of the sensing unit SU may be improved, and the resistance of the electrodes included in the sensing unit SU may be reduced. In this case, it may be more advantageous to secure an applicable frequency range (e.g., bandwidth) for the signal provided to the sensor layer 200. Therefore, the degree of freedom in frequency selection may be improved.

According to one or more embodiments of the present disclosure, each first pattern 211 may have a ring shape, and a portion of each second divided electrode 230-dp overlapping with the first pattern 211 may be close to a bar shape. In this case, the overlapping surface area between the first electrode 210 and the third electrode 230 may be suitably adjusted by controlling an inner diameter size of each first pattern 211 or a width of each second divided electrode 230-dp.

According to one or more embodiments of the present disclosure, the first divided electrode 210-dp may include the first patterns 211 and first bridge patterns 212 located on different respective layers, and the first patterns 211 and first bridge patterns 212 may be electrically connected through contact. In this case, compared to when the first patterns 211 and first bridge patterns 212 are provided integrally on the same layer, the resistance may relatively increase.

In one or more embodiments of the present disclosure, a portion of the second divided electrode 230-dp overlapping the first pattern 211 may have resistance that is lower than that of the first pattern 211. However, this is merely an example, depending on the size of the width of the ring of the first pattern 211 or the portion of the second divided electrode 230-dp, the resistance relationship may change.

The second divided electrodes 230-dp may extend in the second direction DR2 in the same layer. Therefore, there may be little to no increase in resistance due to layer changes within the second divided electrode 230-dp. The second divided electrode 230-dp may be an electrode to which a signal is applied in a charging driving mode described later. Therefore, a lower resistance of the second divided electrode 230-dp may result in a stronger current and magnetic field strength for charging the resonance circuit of the pen PN (see FIG. 6).

According to one or more embodiments of the present disclosure, because the portions of the second divided electrodes 230-dp overlapping the first patterns 211 are close to a bar shape, the second divided electrodes 230-dp may have a shape with a relatively narrow width as compared to the first divided electrodes 210-dp. In this case, parasitic capacitance caused by each second divided electrode 230-dp may be reduced. Therefore, the performance of the sensor layer 200 may be improved.

Referring to FIG. 9B, the second divided electrode 230-dp may include a first portion having a first width WT1 in the first direction DR1, and a second portion having a second width WT2 in the first direction DR1. The first width WT1 may be greater than the second width WT2. For example, the first portion having the first width WT1 may be closer to the first bridge patterns 212 than the second portion having the second width WT2.

In a planar view, the first portion having the first width WT1 may overlap the first patterns 211 to generate capacitance. In addition, the second portion having the second width WT2 may overlap a dummy pattern surrounded by the first patterns 211. By adjusting the second width WT2, the overlapping surface area between the first electrode 210 and the third electrode 230 may be suitably controlled.

An opening 230op may be defined in the second divided electrode 230-dp, and two first bridge patterns 212 may be located in the opening 230op. When the first bridge patterns 212 are surrounded by the second divided electrode 230-dp, capacitances that vary with temperature between the capacitances generated in the first electrode 210 may be reduced. Therefore, the temperature characteristics of the sensor layer 200 may be improved.

Referring to FIG. 10A, the second electrode 220 may include a plurality of first branch portions 220b1 extending along the first direction DR1, a plurality of second branch portions 220b2 extending along the second direction DR2 crossing the first direction DR1, and a connection portion 220b3 located between the first patterns 211. The first branch portions 220b1 may be spaced apart from each other in the second direction DR2, and the second branch portions 220b2 may be spaced apart from each other in the first direction DR1. The first branch portions 220b1, the second branch portions 220b2, and the connection portion 220b3 may be connected to each other to have an integral shape.

The auxiliary electrode 240 may correspond to one of the first auxiliary electrodes 240-1 or the second auxiliary electrodes 240-2. Hereinafter, the auxiliary electrode 240 is referred to as a fourth electrode 240.

The fourth electrode 240 may include a plurality of third divided electrodes 240-dp spaced apart from each other in the second direction DR2. Each of the third divided electrodes 240-dp may extend along the first direction DR1. Each of the third divided electrodes 240-dp may include a plurality of second patterns 241, and a plurality of second bridge patterns 242 electrically connected to the second patterns 241. Each of the second patterns 241 may have a ring shape. The second patterns 241 and the second bridge patterns 242 may be electrically connected to each other through contact holes defined in an intermediate insulating layer 203 (see FIG. 7A). Two adjacent second patterns 241 may be spaced apart from each other with one second divided electrode 230-dp and two first bridge patterns 212 in between.

In one or more embodiments of the present disclosure, as shown in FIG. 10B, a third width WT3 of the first branch portions 220b1 in the second direction DR2 may be greater than a fourth width WT4 of the second branch portions 220b2 in the first direction DR1. For example, the first branch portions 220b1 may overlap the second patterns 241 and the dummy pattern surrounded by the second patterns 241. By adjusting the third width WT3, an overlapping surface area between the second electrode 220 and the fourth electrode 240 may be suitably controlled. Alternatively, the overlapping surface area between the second electrode 220 and the fourth electrode 240 may be suitably controlled by adjusting a size of an inner diameter of the ring shape surrounding the dummy pattern of each second pattern 241.

In one or more embodiments of the present disclosure, each of the third divided electrodes 240-dp may include second patterns 241 and second bridge patterns 242 located on different respective layers, and the second patterns 241 and the second bridge patterns 242 may be electrically connected through contact. In this case, compared to a structure in which the second patterns 241 and the second bridge patterns 242 are provided integrally on the same layer, the resistance may be relatively increased.

In one or more embodiments of the present disclosure, the third electrode 230 corresponds to a structure that transmits signals during touch sensing and pen sensing, and the fourth electrode 240 corresponds to a structure that generates capacitance with the third electrode 230 during pen sensing. Therefore, it is suitable to reduce the resistance of the third electrode 230, rather than reducing the resistance of the fourth electrode 240. Therefore, the third electrode 230 may be implemented in the same layer (e.g., a single layer), and the fourth electrode 240 may be implemented in two different layers.

Referring to FIGS. 9B and 10B, the second bridge pattern 242 may include only one line extending in a first crossing direction CDR1 or a second crossing direction CDR2 in a corresponding section. In this case, the first bridge pattern 212 may cross with the second bridge pattern 242 in a corresponding section in an insulated manner. As a result, capacitance between the first bridge pattern 212 and the second bridge pattern 242 may be reduced or minimized.

Referring to FIGS. 9B and 10B, the second divided electrodes 230-dp, the second patterns 241, the first patterns 211, the second electrode 220, and the second bridge patterns 242 may each have a mesh structure. Each mesh structure may include a plurality of mesh lines. Each of the plurality of mesh lines may have a shape extending in a corresponding direction and may be connected to each other. The shape of the mesh lines may vary, including straight lines, lines with protrusions, or uneven lines. In each mesh structure, openings partially surrounded by the mesh lines may be defined (provided or created). The openings may overlap the emission area PXA (see FIG. 7A), and the mesh lines may overlap the non-emission area NPXA (see FIG. 7A). However, this is not particularly limited.

In FIGS. 9B and 10B, the mesh structure is illustrated as including mesh lines extending along the first crossing direction CDR1 crossing the first direction DR1 and the second direction DR2, and mesh lines extending along the second crossing direction CDR2 crossing the first crossing direction CDR1. However, the extending direction of the mesh lines constituting the mesh structure is not limited to the illustration in FIGS. 9B and 10B. For example, the mesh structure may include mesh lines extending only in the first direction DR1 and the second direction DR2, or it may include mesh lines extending in the first direction DR1, the second direction DR2, and the first and second crossing directions CDR1 and CDR2. That is, the mesh structure may be modified into various shapes.

In one or more embodiments of the present disclosure, a first capacitor may be defined between the first electrode 210 and the third electrode 230, and a second capacitor may be defined between the second electrode 220 and the fourth electrode 240. The first capacitance of the first capacitor and the second capacitance of the second capacitor may be adjusted by the overlapping surface area between the first electrode 210 and the third electrode 230, and the overlapping surface area between the second electrode 220 and the fourth electrode 240.

As the first and second capacitances increase, an amount of induced current transferred from the third electrode 230 to the first electrode 210 may increase, and an amount of induced current transferred from the fourth electrode 240 to the second electrode 220 may increase. Therefore, as the first and second capacitances increase, the pen-sensing performance of the sensor layer 200 may be improved. Additionally, during touch sensing, the first and second capacitances may act as a load. Therefore, as the first and second capacitances decrease, the touch-sensing performance may be improved.

According to the present disclosure, the overlapping surface area between the first electrode 210 and the third electrode 230, and the overlapping surface area between the second electrode 220 and the fourth electrode 240, may be suitably controlled. Therefore, the sensor layer 200 with capacitances at appropriate levels, considering both touch sensitivity and pen-sensing sensitivity, may be provided. As a result, the electronic device 1000 (see FIG. 2A) with improved pen sensitivity and touch sensitivity may be provided.

In one or more embodiments of the present disclosure, a surface area occupied by components included in the first electrode 210 and the second electrode 220 within a second conductive layer SU204 of one sensing unit SU may be greater than that occupied by components included in the third electrode 230 and the fourth electrode 240. Changes in capacitance caused by the first input 2000 (see FIG. 6) may be greater when the distance is closer. Therefore, components for sensing the first input 2000 (see FIG. 6) may be located with a relatively larger area on a layer adjacent to a surface of the electronic device 1000 (see FIG. 2A). As a result, the touch performance may be improved.

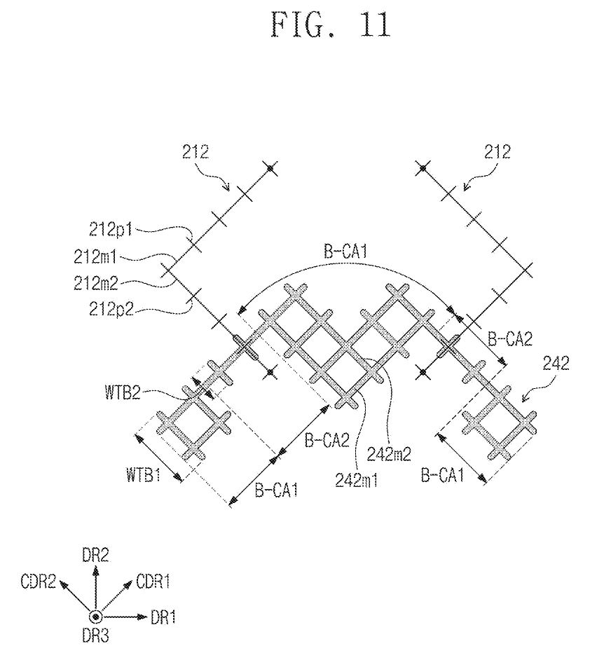

FIG. 11 is a plan view illustrating a portion of components of the sensing unit according to one or more embodiments of the present disclosure.

Referring to FIG. 11, for example, one second bridge pattern 242, and two first bridge patterns 212 overlapping the second bridge pattern 242, are illustrated.

Each of the first bridge patterns 212 may include a first main line 212m1 extending in the first crossing direction CDR1, and a second main line 212m2 extending in the second crossing direction CDR2. One end of the first main line 212m1 and one end of the second main line 212m2 may cross each other. The first bridge pattern 212 may further include a plurality of first protruding lines 212p1 crossing the first main line 212m1, and a plurality of second protruding lines 212p2 crossing the second main line 212m2. Each of the first protruding lines 212p1 may be spaced apart from each other in the first crossing direction CDR1, and each of the second protruding lines 212p2 may be spaced apart from each other in the second crossing direction CDR2. In one or more other embodiments of the present disclosure, the first protruding lines 212p1 and the second protruding lines 212p2 may be omitted.

The second bridge pattern 242 may include first lines 242m1 extending along the first crossing direction CDR1, and second lines 242m2 extending along the second crossing direction CDR2. According to one or more embodiments of the present disclosure, the second bridge pattern 242 may include first portions B-CA1 where two or more first lines 242m1 and two or more second lines 242m2 cross, and second portions B-CA2 where one first line 242m1 crosses with one or more second lines 242m2, or where one or more first lines 242m1 cross with one second line 242m2. The second portions B-CA2 may each cross with the first bridge patterns 212.

In one or more embodiments, each of the first portions B-CA1 may include at least two lines extending in the same direction, and each of the second portions B-CA2 may include only one line extending in the same direction. Therefore, a minimum width WTB1 of the first portions B-CA1 may be greater than a minimum width WTB2 of the second portions B-CA2.

In the second portions B-CA2, the first bridge patterns 212 may cross with the second bridge pattern 242 in an insulated manner. In this case, the capacitance between the first bridge patterns 212 and the second bridge pattern 242 may be reduced. Additionally, because the remaining portions of the second bridge pattern 242 not overlapping the first bridge patterns 212 are provided in a manner in which two or more first lines 242m1 and two or more second lines 242m2 cross, the probability of visually recognizing the second bridge pattern 242 due to the difference in external light reflectance may be reduced.

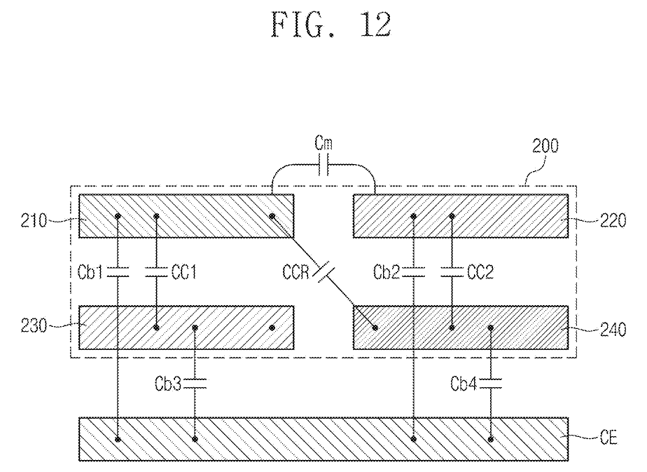

FIG. 12 is a diagram illustrating capacitors located in the sensor layer 200 according to one or more embodiments of the present disclosure.

Referring to FIG. 12, the first electrode 210, the second electrode 220, the third electrode 230, the fourth electrode 240, and the second electrode CE are shown. The second electrode CE is a component included in the light-emitting element 100PE (see FIG. 7A) and is hereinafter referred to as the common electrode CE.

A first base capacitor Cb1 may be defined between the first electrode 210 and the common electrode CE, a second base capacitor Cb2 may be defined between the second electrode 220 and the common electrode CE, a third base capacitor Cb3 may be defined between the third electrode 230 and the common electrode CE, and a fourth base capacitor Cb4 may be defined between the fourth electrode 240 and the common electrode CE.

A mutual capacitor Cm may be defined between the first electrode 210 and the second electrode 220. The sensor driver 200C (see FIG. 6) may calculate coordinates of the first input 2000 (see FIG. 6) based on a change in capacitance of the mutual capacitor Cm.

A first coupling capacitor CC1 may be defined between the first electrode 210 and the third electrode 230, and a second coupling capacitor CC2 may be defined between the second electrode 220 and the fourth electrode 240. Induced current generated by the second input 3000 (see FIG. 6) may be transferred from the third electrode 230 to the first electrode 210 through the first coupling capacitor CC1, and may be transferred from the fourth electrode 240 to the second electrode 220 through the second coupling capacitor CC2.

Additionally, a third coupling capacitor CCR may be defined between the first electrode 210 and the fourth electrode 240. An electric charge introduced from the fourth electrode 240 to the first electrode 210 through the third coupling capacitor CCR may affect the change in capacitance of the mutual capacitor Cm between the first electrode 210 and the second electrode 220. For example, the electric charge introduced from the fourth electrode 240 to the first electrode 210 through the third coupling capacitor CCR may increase the capacitance of the mutual capacitor Cm.

According to one or more embodiments of the present disclosure, because the impedance of the first auxiliary electrode group 240G1 and the second auxiliary electrode group 240G2 may be designed to be substantially the same, difference in capacitance change of the mutual capacitor Cm caused by the first auxiliary electrode group 240G1 (see FIG. 8) and the second auxiliary electrode group 240G2 (see FIG. 8) may be reduced or minimized. As this difference decreases, the probability of malfunction due to touch errors may be reduced or eliminated. As a result, the touch reliability of the sensor layer 200 (see FIG. 8) may be improved.

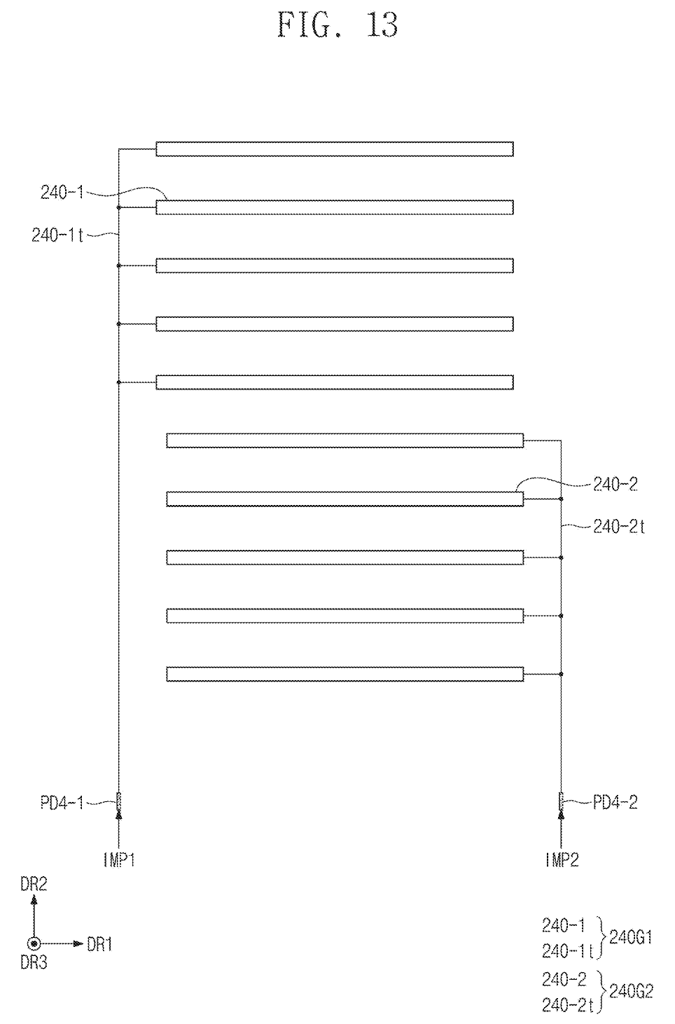

FIG. 13 is a plan view illustrating a portion of components of the sensor layer according to one or more embodiments of the present disclosure.

Referring to FIG. 13, for example, illustrated are a first auxiliary electrode group 240G1a, second auxiliary electrode group 240G2, a first auxiliary trace line 240-1t, a second auxiliary trace line 240-2t , a (4-1)-th pad PD4-1 connected to the first auxiliary electrode group 240G1 and to the first auxiliary trace line 240-1t, and a (4-2)-th pad PD4-2 connected to the second auxiliary electrode group 240G2 and to the second auxiliary trace line 240-2t.

A first impedance IMP1 of the first auxiliary electrode group 240G1 and the (4-1)-th pad PD4-1, and a second impedance IMP2 of the second auxiliary electrode group 240G2 and the (4-2)-th pad PD4-2 may be substantially the same/substantially equal. Here, "substantially the same" may mean that the first impedance IMP1 and the second impedance IMP2 are the same within a corresponding error range, which may be less than about 5%.

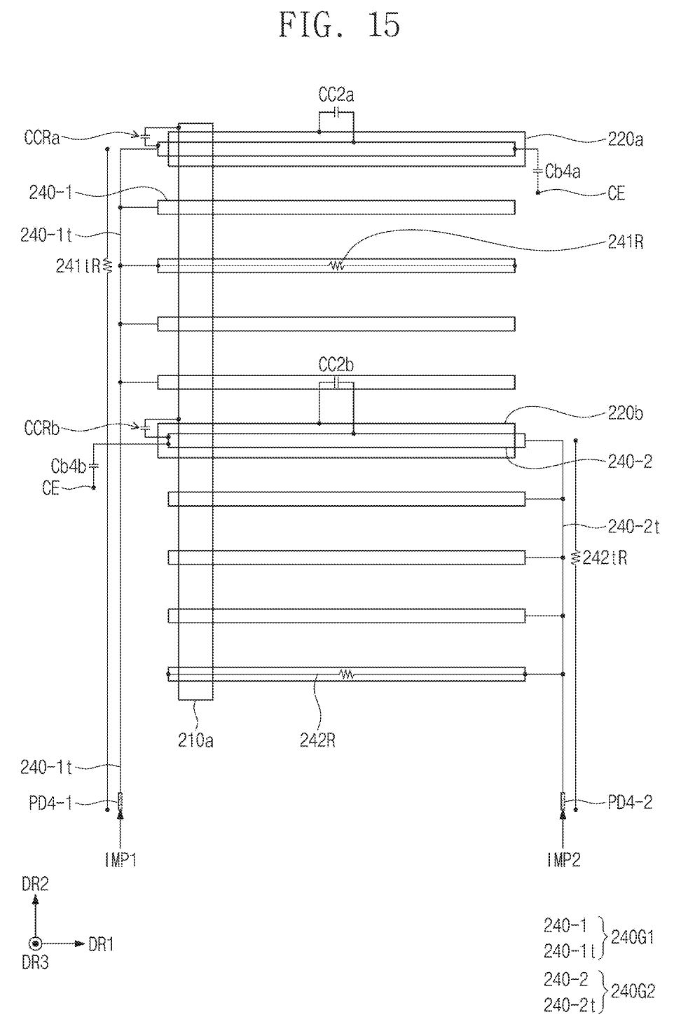

Various designs may be applied to ensure the first impedance IMP1 and the second impedance IMP2 are the same or substantially equal, and corresponding descriptions are provided with reference to FIGS. 15 to 19.

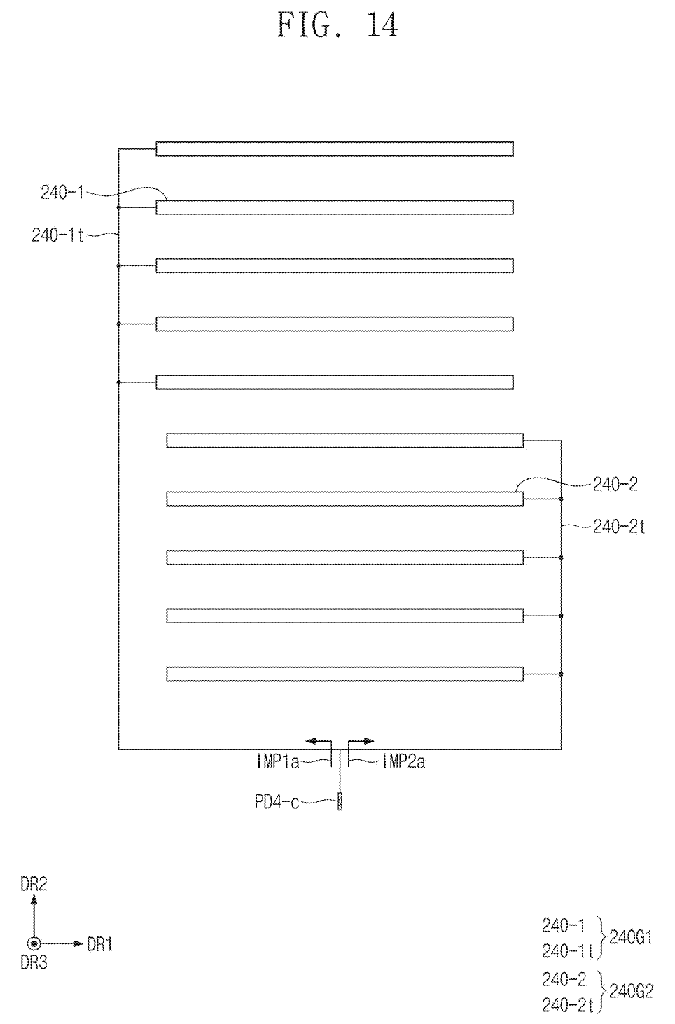

FIG. 14 is a plan view illustrating a portion of components of the sensor layer according to one or more embodiments of the present disclosure.

Referring to FIG. 14, illustrated are a fourth pad PD4-C connected to the first auxiliary electrode group 240G1 and to the second auxiliary electrode group 240G2. That is, in one or more embodiments of the present disclosure, the first auxiliary electrode group 240G1 and the second auxiliary electrode group 240G2 may be connected to the same pad, for example, to the fourth pad PD4-C.

Based on a branching point at the fourth pad PD4-C, the first impedance IMP1a of the first auxiliary electrode group 240G1 and the second impedance IMP2a of the second auxiliary electrode group 240G2 may be substantially the same/may be substantially equal.

As described in FIGS. 13 and 14, the first impedance IMP1/IMP1a of the first auxiliary electrode group 240G1 and the second impedance IMP2/IMP2a of the second auxiliary electrode group 240G2 are matched to be substantially the same. In this case, deviation in the mutual capacitance caused by the first auxiliary electrode group 240G1 and the second auxiliary electrode group 240G2 may be reduced or minimized. As the deviation decreases, the probability of touch malfunctions may be reduced or eliminated. As a result, the touch reliability of the sensor layer 200 (see FIG. 8) may be improved.

FIG. 15 is a plan view illustrating a portion of components of the sensor layer according to one or more embodiments of the present disclosure.

Referring to FIGS. 8 and 15, the first electrodes 210 may include one first electrode 210a. The second electrodes 220 may include a (2-1)-th electrode 220a and a (2-2)-th electrode 220b. The first electrode 210a may cross with both the first auxiliary electrodes 240-1 and the second auxiliary electrodes 240-2. The (2-1)-th electrode 220a may overlap one of the first auxiliary electrodes 240-1, and the (2-2)-th electrode 220b may overlap one of the second auxiliary electrodes 240-2.

FIG. 15 schematically illustrates variables that may be determined (or set, or designed) to match the impedances of the first auxiliary electrode group 240G1 and the second auxiliary electrode group 240G2. These variables may include resistances and capacitances.

For example, resistances may include a first resistance 241R of each first auxiliary electrode 240-1, a second resistance 242R of each second auxiliary electrode 240-2, a first trace resistance 241tR of the first auxiliary trace line 240-1t, and a second trace resistance 242tR of the second auxiliary trace line 240-2t. The first trace resistance 241tR may correspond to the resistance of the first auxiliary trace line 240-1t from the contact points connected to the first auxiliary electrodes 240-1 to the (4-1)-th pad PD4-1. Similarly, the second trace resistance 242tR may correspond to the resistance of the second auxiliary trace line 240-2t from the contact points connected to the second auxiliary electrodes 240-2 to the (4-2)-th pad PD4-2.

For example, the capacitors may include a first coupling capacitor CCRa between one first auxiliary electrode 240-1 and the first electrode 210a, a second coupling capacitor CCRb between one second auxiliary electrode 240-2 and the first electrode 210a, a third coupling capacitor CC2a between one first auxiliary electrode 240-1 and the (2-1)-th electrode 220a, a fourth coupling capacitor CC2b between one second auxiliary electrode 240-2 and the (2-2)-th electrode 220b, a first base capacitor Cb4a between one first auxiliary electrode 240-1 and the common electrode CE, and a second base capacitor Cb4b between one second auxiliary electrode 240-2 and the common electrode CE.

In one or more embodiments of the present disclosure, the first impedance IMP1 of the first auxiliary electrode group 240G1 and the second impedance IMP2 of the second auxiliary electrode group 240G2 may be substantially the same. For example, in one or more embodiments of the present disclosure, the first auxiliary electrode group 240G1 may have the same resistance as the second auxiliary electrode group 240G2, and the first auxiliary electrode group 240G1 may have the same capacitive reactance as the second auxiliary electrode group 240G2. Alternatively, in one or more other embodiments of the present disclosure, the first auxiliary electrode group 240G1 may have a resistance that is greater than that of the second auxiliary electrode group 240G2, and the first auxiliary electrode group 240G1 may have a capacitive reactance that is less than that of the second auxiliary electrode group 240G2.

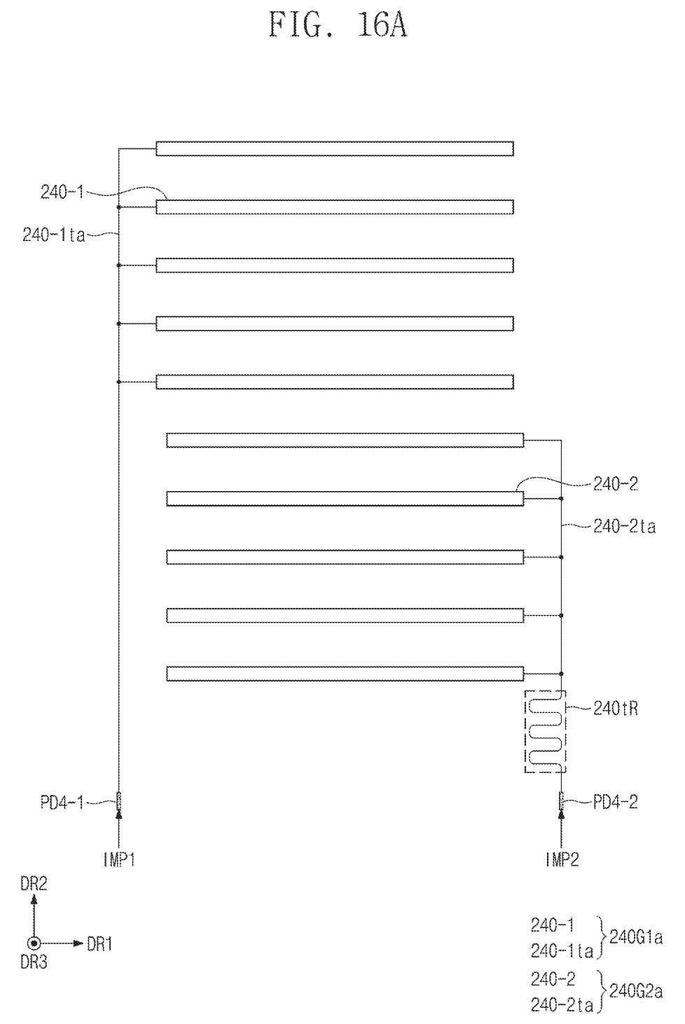

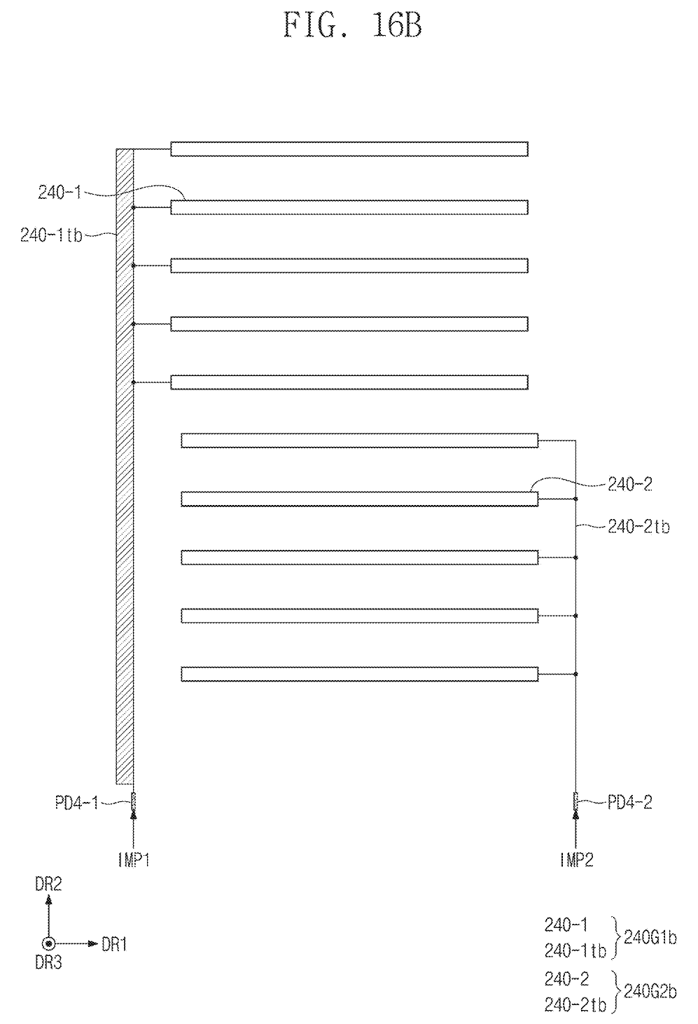

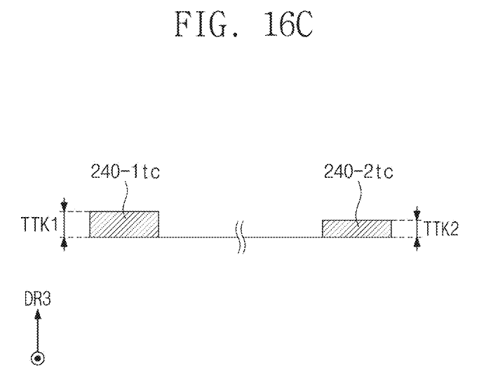

FIG. 16A is a plan view illustrating a portion of components of the sensor layer according to one or more embodiments of the present disclosure.

Referring to FIGS. 15 and 16A, the first impedance IMP1 of the first auxiliary electrode group 240G1a and the second impedance IMP2 of the second auxiliary electrode group 240G2a may be substantially the same. For example, the first auxiliary electrode group 240G1a may have the same resistance as the second auxiliary electrode group 240G2a, and the first auxiliary electrode group 240G1a may have the same capacitive reactance as the second auxiliary electrode group 240G2a.

In one or more embodiments of the present disclosure, the first auxiliary electrode group 240G1a may include first auxiliary electrodes 240-1, and a first auxiliary trace line 240-1ta electrically connected to the first auxiliary electrodes 240-1. The second auxiliary electrode group 240G2a may include second auxiliary electrodes 240-2, and a second auxiliary trace line 240-2ta electrically connected to the second auxiliary electrodes 240-2.

In one or more embodiments, the first resistance 241R of each of the first auxiliary electrodes 240-1 and the second resistance 242R of each of the second auxiliary electrodes 240-2 may be substantially the same, or substantially equal. Additionally, the first trace resistance 241tR of the first auxiliary trace line 240-1ta and the second trace resistance 242tR of the second auxiliary trace line 240-2ta may be substantially the same, or substantially equal.

The first auxiliary electrodes 240-1 may be spaced apart from the (4-1)-th pad PD4-1 and the (4-2)-th pad PD4-2 farther than, or to a greater degree than, the second auxiliary electrodes 240-2. Therefore, the second auxiliary trace line 240-2ta may further include a bend portion 240tR. The bend portion 240tR may have a wave-like shape. Thus, the second trace resistance 242tR of the second auxiliary trace line 240-2ta may be designed to be the same as the first trace resistance 241tR of the first auxiliary trace line 240-1ta.

Capacitance of the first coupling capacitor CCRa between one first auxiliary electrode 240-1 and one first electrode 210a, and capacitance of the second coupling capacitor CCRb between one second auxiliary electrode 240-2 and one first electrode 210a, may be substantially the same, or substantially equal. Additionally, capacitance of the third coupling capacitor CC2a between one first auxiliary electrode 240-1 and the (2-1)-th electrode 220a, and capacitance of the fourth coupling capacitor CC2b between one second auxiliary electrode 240-2 and the (2-2)-th electrode 220b, may be substantially the same, or substantially equal. Moreover, capacitance of the first base capacitor Cb4a between one first auxiliary electrode 240-1 and the common electrode CE, and capacitance of the second base capacitor Cb4b between one second auxiliary electrode 240-2 and the common electrode CE, may be substantially the same, or substantially equal.

FIG. 16B is a plan view illustrating a portion of components of the sensor layer according to one or more embodiments of the present disclosure. In the explanation for FIG. 16B, the same reference numerals as in FIG. 16A are used, and detailed descriptions are omitted.

Referring to FIGS. 15 and 16B, the first impedance IMP1 of the first auxiliary electrode group 240G1b, and the second impedance IMP2 of the second auxiliary electrode group 240G2b, may be substantially the same. For example, the first auxiliary electrode group 240G1a may have the same resistance as the second auxiliary electrode group 240G2a, and may have the same capacitive reactance as second auxiliary electrode group 240G2a.

In one or more embodiments of the present disclosure, the first auxiliary electrode group 240G1b may include first auxiliary electrodes 240-1, and a first auxiliary trace line 240-1tb electrically connected to the first auxiliary electrodes 240-1. The second auxiliary electrode group 240G2b may include second auxiliary electrodes 240-2, and a second auxiliary trace line 240-2tb electrically connected to the second auxiliary electrodes 240-2.

In one or more embodiments, the first trace resistance 241tR of the first auxiliary trace line 240-1tb, and the second trace resistance 242tR of the second auxiliary trace line 240-2tb, may be substantially the same, or substantially equal.

The first auxiliary electrodes 240-1 may be spaced apart from the (4-1)-th pad PD4-1 and the (4-2)-th pad PD4-2 to a greater degree than, or farther than, the second auxiliary electrodes 240-2. Therefore, a portion of the first auxiliary trace line 240-1tb may have a width that is greater than that of the second auxiliary trace line 240-2tb. Thus, the first trace resistance 241tR of the first auxiliary trace line 240-1tb, which has a relatively long length, may be reduced to the same level as the second trace resistance 242tR of the second auxiliary trace line 240-2tb.

FIG. 16C is a cross-sectional view illustrating a portion of the components of the sensor layer according to one or more embodiments of the present disclosure. In describing FIG. 16C, the same reference numerals as those used for the components described in FIG. 16A are provided, and detailed descriptions thereof are omitted.

Referring to FIGS. 15 and 16C, a portion of the first auxiliary trace line 240-1tc may have a thickness TTK1 that is greater than a thickness TTK2 of the second auxiliary trace line 240-2tc. Thus, the first trace resistance 241tR of the first auxiliary trace line 240-1tc, which has a relatively long length, may be reduced to the same level as the second trace resistance 242tR of the second auxiliary trace line 240-2tc.

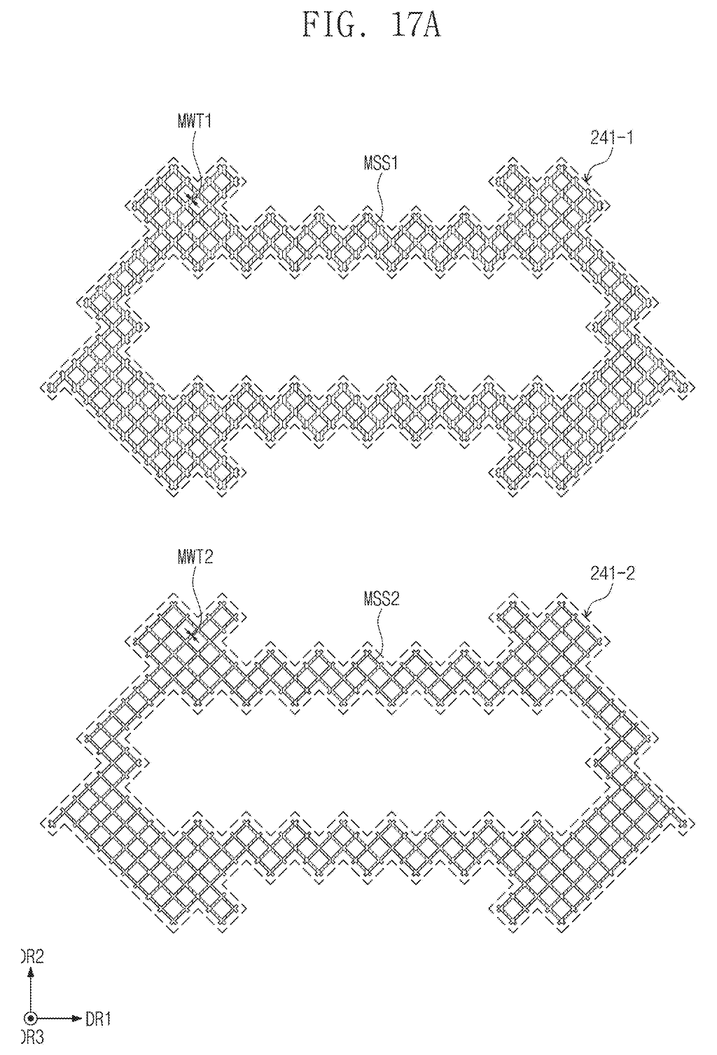

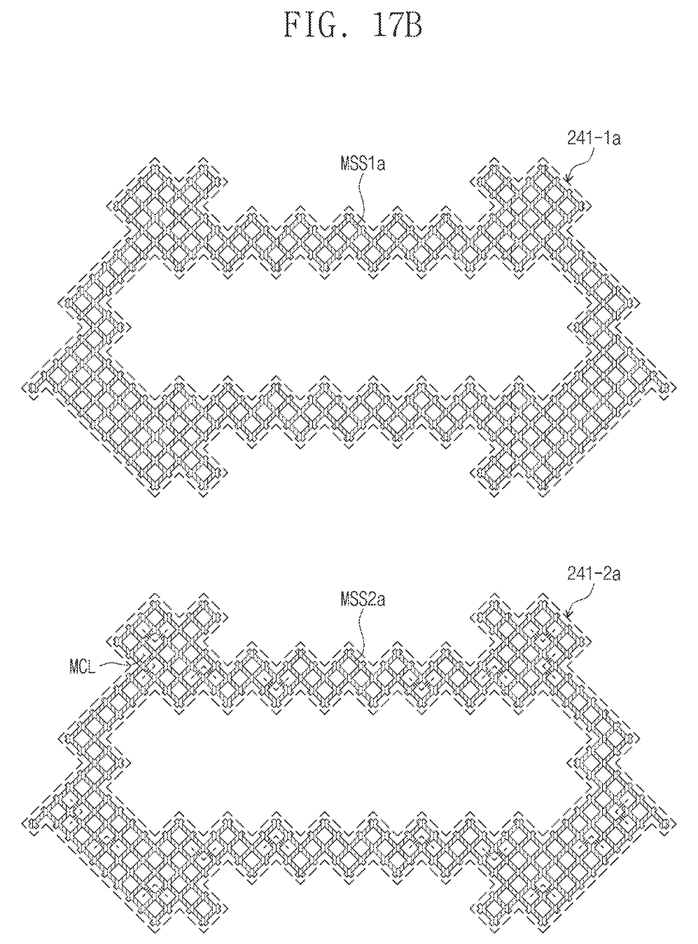

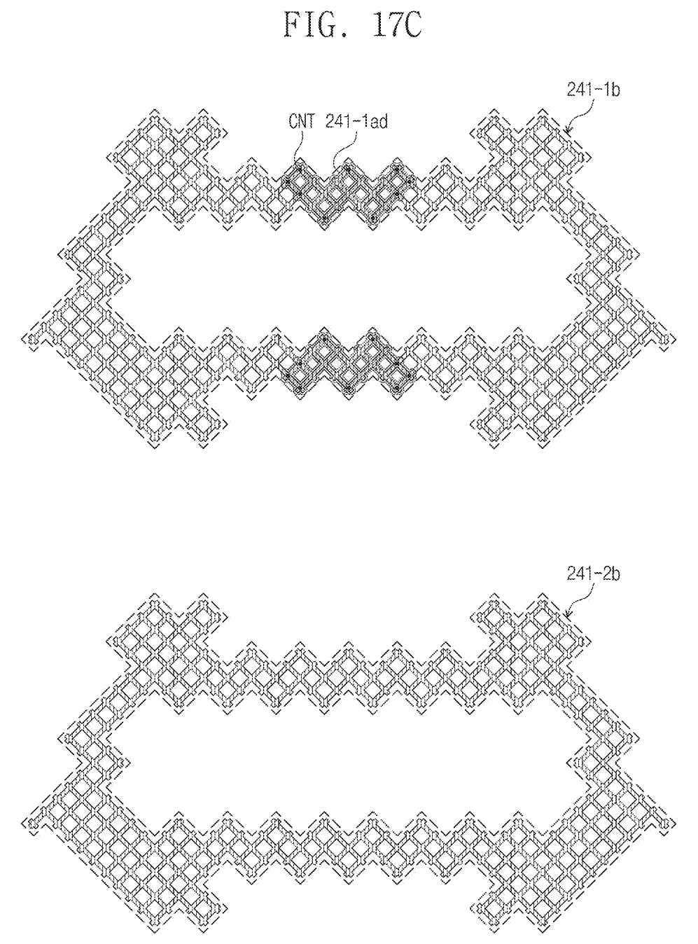

FIG. 17A is a plan view illustrating a portion of the components of a sensor layer according to one or more embodiments of the present disclosure. FIG. 17B is a plan view illustrating a portion of the components of the sensor layer according to one or more embodiments of the present disclosure. FIG. 17C is a plan view illustrating a portion of the components of the sensor layer according to one or more embodiments of the present disclosure.

Referring to FIGS. 15, 17A, 17B, and 17C, the first trace resistance 241tR of the first auxiliary trace line 240-1t, which has a relatively long length, may be greater than the second trace resistance 242tR of the second auxiliary trace line 240-2t. In this case, to match the first impedance IMP1 of the first auxiliary electrode group 240G1 with the second impedance IMP2 of the second auxiliary electrode group 240G2, the first resistance 241R of each first auxiliary electrode 240-1 may be adjusted to be lower than the second resistance 242R of each second auxiliary electrode 240-2.

FIGS. 17A, 17B and 17C illustrate embodiments in which the first resistance 241R of each first auxiliary electrode 240-1 is designed to be less than the second resistance 242R of each second auxiliary electrode 240-2.

Referring to FIGS. 15 and 17A, for example, a second pattern 241-1 (hereinafter referred to as a first auxiliary pattern) included in the first auxiliary electrodes 240-1 and a second pattern 241-2 (hereinafter referred to as a second auxiliary pattern) included in the second auxiliary electrodes 240-2 are illustrated.

The first auxiliary pattern 241-1 may have a first mesh structure MSS1, and the second auxiliary pattern 241-2 may have a second mesh structure MSS2. A surface area occupied by the first mesh structure MSS1 within the same surface area (e.g., a percentage of area occupied by the first mesh structure MSS1 in a unit area) may be larger than that occupied by the second mesh structure MSS2. That is, the resistance of the first auxiliary pattern 241-1, which has a relatively larger surface area, may be less than that of the second auxiliary pattern 241-2. Therefore, the overall resistance of the first auxiliary electrode group 240G1 and the overall resistance of the second auxiliary electrode group 240G2 may be substantially the same.

The first mesh structure MSS1 of the first auxiliary pattern 241-1 may have a first width MWT1, and the second mesh structure MSS2 of the second auxiliary pattern 241-2 may have a second width MWT2. The first width MWT1 may be greater than the second width MWT2. Therefore, the first resistance 241R of each first auxiliary electrode 240-1 may be less than the second resistance 242R of each second auxiliary electrode 240-2.

Referring to FIGS. 15 and 17B, illustrated are, for example, a second pattern 241-1a (hereinafter referred to as the first auxiliary pattern) included in the first auxiliary electrodes 240-1, and a second pattern 241-2a (hereinafter referred to as the second auxiliary pattern) included in the second auxiliary electrodes 240-2.

The first auxiliary pattern 241-1a may have a first mesh structure MSS1a, and the second auxiliary pattern 241-2a may have a second mesh structure MSS2a. According to one or more embodiments of the present disclosure, at least a portion of the second mesh structure MSS2a of the second auxiliary pattern 241-2 may be omitted. For example, a cutting line MCL is illustrated within the second mesh structure MSS2a. A portion of the second mesh structure MSS2a may be omitted corresponding to an area where the cutting line MCL is indicated. Patterns with relatively more cutting lines MCL may have higher resistance. Therefore, the second auxiliary pattern 241-2a may have a greater resistance than the first auxiliary pattern 241-1a, and the first resistance 241R of each first auxiliary electrode 240-1 may be less than the second resistance 242R of each second auxiliary electrode 240-2.

Referring to FIGS. 15 and 17C, for example, a second pattern 241-1b (hereinafter referred to as the first auxiliary pattern) included in the first auxiliary electrodes 240-1, an additional auxiliary pattern 241-1ad electrically connected to the first auxiliary pattern 241-1b, and a second pattern 241-2b (hereinafter referred to as the second auxiliary pattern) included in the second auxiliary electrodes 240-2 are illustrated.

The additional auxiliary pattern 241-1ad may be located on a different layer from the first auxiliary pattern 241-1b, and may be electrically connected to the first auxiliary pattern 241-1b through a contact CNT. For example, when the first auxiliary pattern 241-1b is included in the first conductive layer 202 (refer to FIG. 7A), the additional auxiliary pattern 241-1ad may be included in the second conductive layer 204 (refer to FIG. 7A). Therefore, the contact CNT may be provided in the intermediate insulating layer 203 (refer to FIG. 7A). According to the addition of the auxiliary pattern 241-1ad, the first resistance 241R of each first auxiliary electrode 240-1 may be less than the second resistance 242R of each second auxiliary electrode 240-2.

Examples in which each first resistance 241R of the first auxiliary electrodes 240-1 is designed to be less than each second resistance 242R of the second auxiliary electrodes 240-2 have been described with reference to FIGS. 17A, 17B, and 17C. However, various structures for creating differences in resistance may be applied in addition to the above examples. For example, the second bridge pattern 242 included in the first auxiliary electrodes 240-1 may have a shape different from that of the second bridge pattern 242 included in the second auxiliary electrodes 240-2, as shown in FIG. 11. Alternatively, the number of contacts where the second pattern 241 of the first auxiliary electrodes 240-1 is connected to the second bridge pattern 242, as shown in FIG. 8A, may be greater than the number of contacts where the second pattern 241 of the second auxiliary electrodes 240-2 is connected to the second bridge pattern 242, as shown in FIG. 8A.

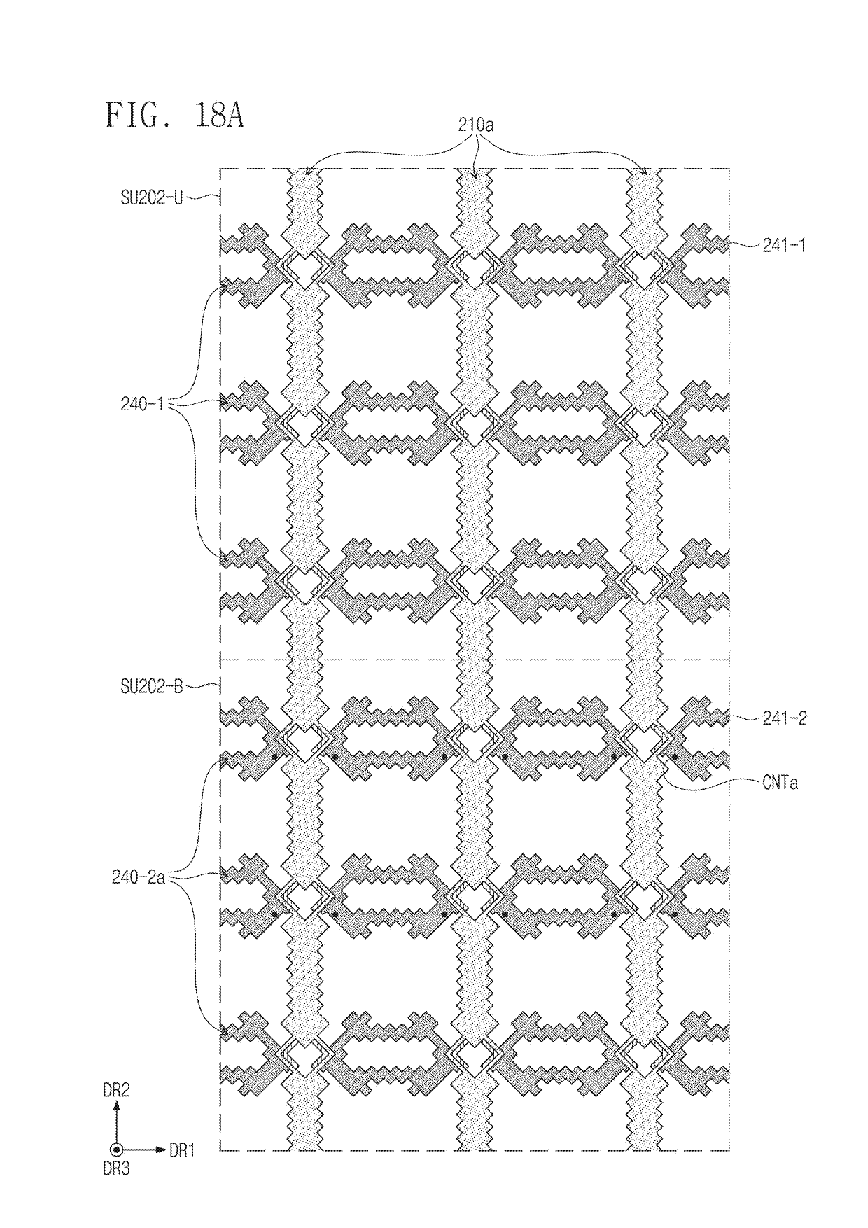

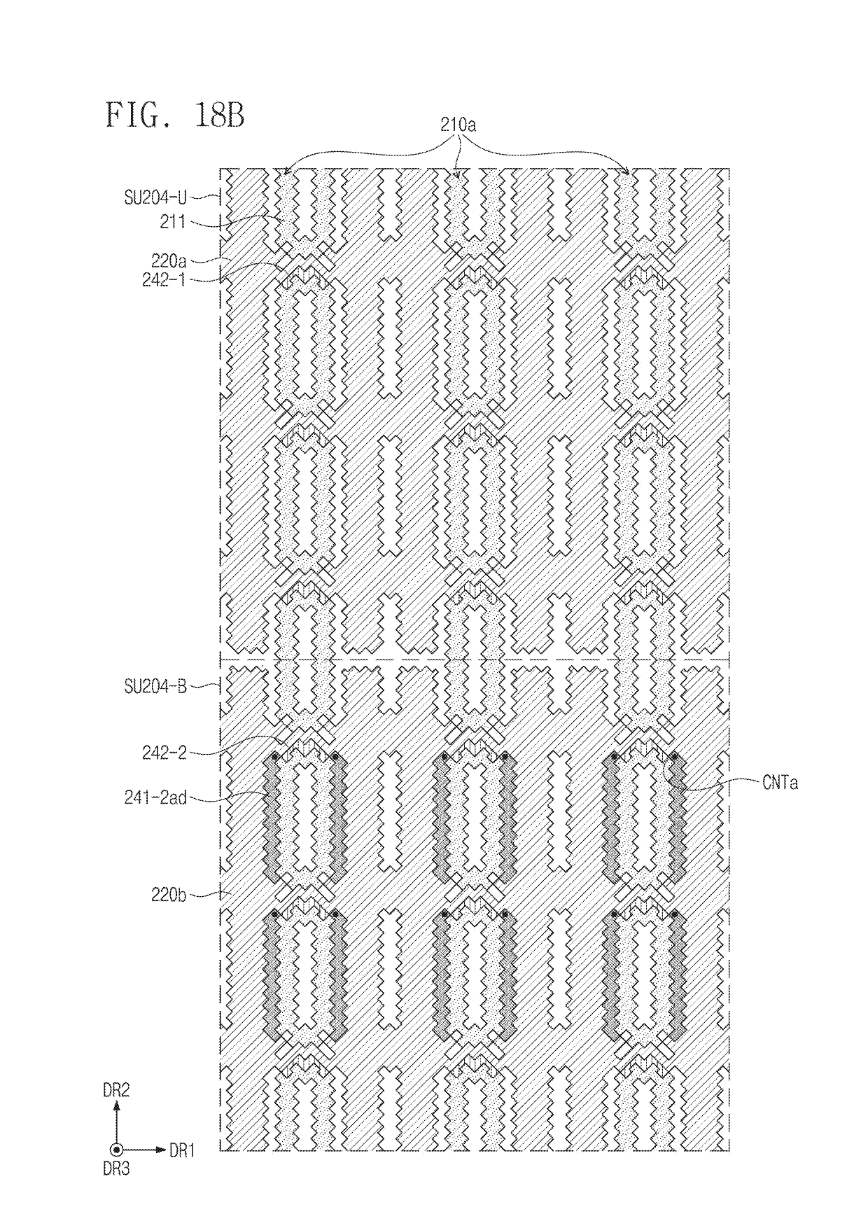

FIG. 18A is a plan view illustrating a portion of the components of the sensor layer according to one or more embodiments of the present disclosure.

FIG. 18B is a plan view illustrating a portion of the components of the sensor layer according to one or more embodiments of the present disclosure.

FIG. 18A illustrates a first conductive layer SU202-U of one sensing unit overlapping the first auxiliary electrode 240-1, and a first conductive layer SU202-B of one sensing unit overlapping the second auxiliary electrode 240-2a. FIG. 18B illustrates a second conductive layer SU204-U of one sensing unit overlapping the first auxiliary electrode 240-1, and a second conductive layer SU204-B of one sensing unit overlapping the second auxiliary electrode 240-2a. The first conductive layers SU202-U and SU202-B may be included in the first conductive layer 202 shown in FIG. 7A, and the second conductive layers SU204-U and SU204-B may be included in the second conductive layer 204 shown in FIG. 7A.

Referring to FIGS. 15, 18A and 18B, the first trace resistance 241tR of the first auxiliary trace line 240-1t, which has a relatively long length, may be greater than the second trace resistance 242tR of the second auxiliary trace line 240-2t. In this case, to match the first impedance IMP1 of the first auxiliary electrode group 240G1 with the second impedance IMP2 of the second auxiliary electrode group 240G2, the capacitive reactance of the first auxiliary electrode group 240G1 may be designed to be less than that of the second auxiliary electrode group 240G2.

In one or more embodiments of the present disclosure, the capacitor defined by the first auxiliary electrode 240-1 may have capacitance that is less than that of the capacitor defined by the second auxiliary electrode 240-2a. For example, the capacitance of the first coupling capacitor CCRa between one first auxiliary electrode 240-1 and one first electrode 210a may be less than that of the second coupling capacitor CCRb between one second auxiliary electrode 240-2a and one first electrode 210a. Additionally, the capacitance of the third coupling capacitor CC2a between one first auxiliary electrode 240-1 and the (2-1)-th electrode 220a may be less than that of the fourth coupling capacitor CC2b between one second auxiliary electrode 240-2 and the (2-2)-th electrode 220b.

The first auxiliary electrode 240-1 may include a plurality of second patterns 241-1 and a plurality of second bridge patterns 242-1 electrically connected to the second patterns 241-1. The second auxiliary electrode 240-2a may include a plurality of second patterns 241-2, a plurality of second bridge patterns 242-2 electrically connected to the second patterns 241-2, and a plurality of additional auxiliary patterns 241-2ad electrically connected to the second patterns 241-2. The additional auxiliary patterns 241-2ad may be electrically connected to the second patterns 241-2 through a plurality of contacts CNTa. The additional auxiliary patterns 241-2ad may be referred to as a (2-1)-th layer auxiliary electrodes, and the second patterns 241-2 may be referred to as a (2-2)-th layer auxiliary electrodes.

Each additional auxiliary pattern 241-2ad may be located between the (2-2)-th electrode 220b and one first electrode 210a. Due to the additional auxiliary patterns 241-2ad, the capacitance of the second coupling capacitor CCRb between the second auxiliary electrode 240-2a and one first electrode 210a may be greater than that of the first coupling capacitor CCRa between the first auxiliary electrode 240-1 and one first electrode 210a. Additionally, due to the additional auxiliary patterns 241-2ad, the capacitance of the fourth coupling capacitor CC2b between the second auxiliary electrode 240-2a and the (2-2)-th electrode 220b may be greater than that of the third coupling capacitor CC2a between the first auxiliary electrode 240-1 and the (2-1)-th electrode 220a. That is, the capacitance of the capacitor defined by the second auxiliary electrode 240-2a may be greater than that of the capacitor defined by the first auxiliary electrode 240-1.

FIG. 19 is a cross-sectional view illustrating a portion of the components of the sensor layer and the second electrode according to one or more embodiments of the present disclosure.

Referring to FIG. 15 and FIG. 19, the first trace resistance 241tR of the first auxiliary trace line 240-1t, which has a relatively long length, may be greater than the second trace resistance 242tR of the second auxiliary trace line 240-2t. In this case, to match the first impedance IMP1 of the first auxiliary electrode group 240G1 with the second impedance IMP2 of the second auxiliary electrode group 240G2, the capacitive reactance of the first auxiliary electrode group 240G1 may be designed to be less than that of the second auxiliary electrode group 240G2.

In one or more embodiments of the present disclosure, the capacitor defined by the first auxiliary electrode 240-1a may have capacitance that is less than that of the capacitor defined by the second auxiliary electrode 240-2b. For example, the capacitance of the first base capacitor Cb4a1 between the first auxiliary electrode 240-1a and the common electrode CE may be less than that of the second base capacitor Cb4b1 between the second auxiliary electrode 240-2b and the common electrode CE.

In one or more embodiments of the present disclosure, the intermediate insulating layer 203 may be an organic layer. Therefore, by adjusting surface areas of the electrodes located above and below the intermediate insulating layer 203, the capacitance of the base capacitor may be controlled.

The first auxiliary electrode 240-1a may include a (1-1)-th layer auxiliary electrode 240-1L1 located above the display layer 100, and a (1-2)-th layer auxiliary electrode 240-1L2 located above the (1-1)-th layer auxiliary electrode 240-1L1. The second auxiliary electrode 240-2b may include a (2-1)-th layer auxiliary electrode 240-2L1 located above the display layer 100, and a (2-2)-th layer auxiliary electrode 240-2L2 located above the (2-1)-th layer auxiliary electrode 240-2L1. The (1-1)-th layer auxiliary electrode 240-1L1 and the (2-1)-th layer auxiliary electrode 240-2L1 may be located between the display layer 100 and the intermediate insulating layer 203, and the (1-2)-th layer auxiliary electrode 240-1L2 and the (2-2)-th layer auxiliary electrode 240-2L2 may be spaced apart from the display layer 100 with the intermediate insulating layer 203 in between.

In one or more embodiments of the present disclosure, a portion of the second auxiliary electrode 240-2b located between the display layer 100 and the intermediate insulating layer 203, such as the (2-1)-th layer auxiliary electrode 240-2L1, may have a surface area that is larger than a portion of the first auxiliary electrode 240-1a, such as the (1-1)-th layer auxiliary electrode 240-1L1, located between the display layer 100 and the intermediate insulating layer 203. Therefore, the capacitance of the first base capacitor Cb4a1 between the first auxiliary electrode 240-1a and the common electrode CE may be less than that of the second base capacitor Cb4b1between the second auxiliary electrode 240-2b and the common electrode CE.

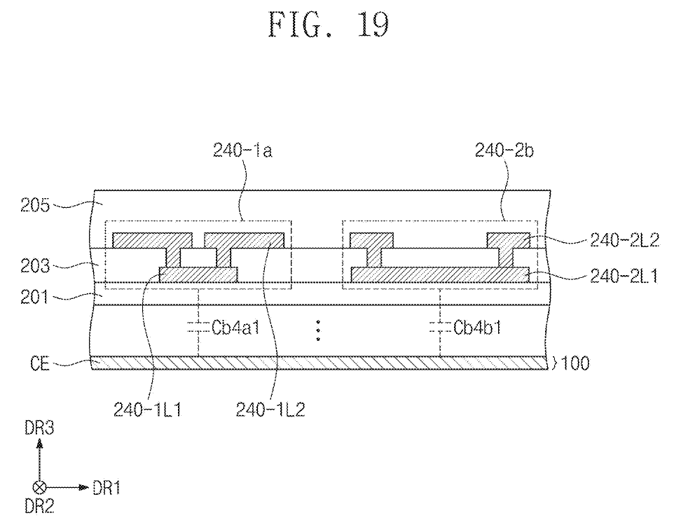

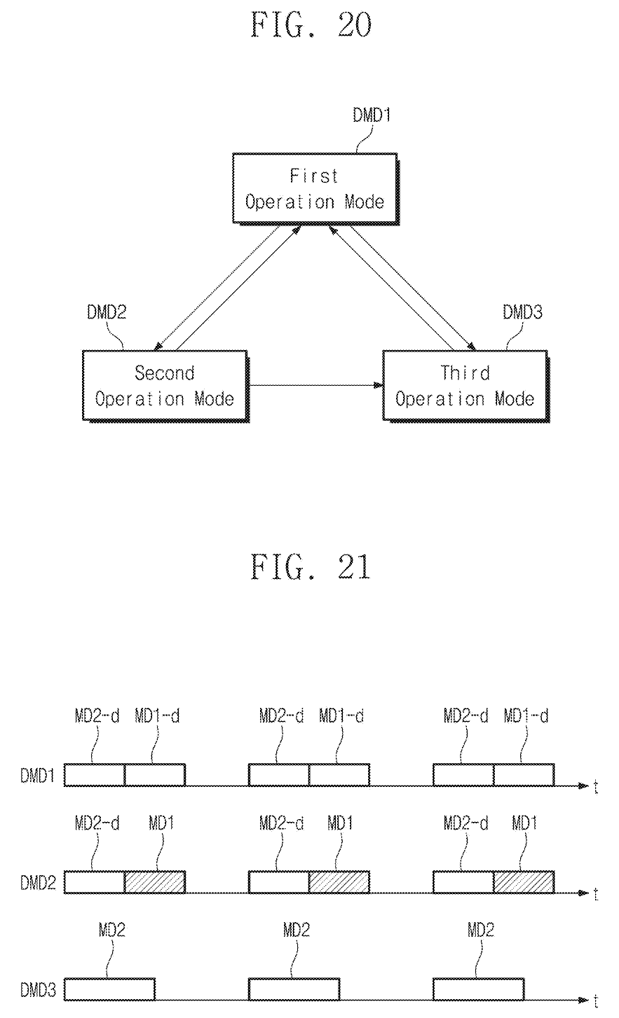

FIG. 20 is a diagram illustrating the operation of the sensor driver 200C (see FIG. 6) according to one or more embodiments of the present disclosure.

Referring to FIG. 6 and FIG. 20, the sensor driver 200C may be configured to be selectively driven in one of a first operation mode DMD1, a second operation mode DMD2, and a third operation mode DMD3.

The first operation mode DMD1 may be referred to as a touch and pen standby mode, the second operation mode DMD2 may be referred to as a touch activation and pen standby mode, and the third operation mode DMD3 may be referred to as a pen activation mode. The first operation mode DMD1 may be a mode in which the first input 2000 and the second input 3000 are in standby. The second operation mode DMD2 may be a mode in which the first input 2000 is sensed and the second input 3000 is in standby. The third operation mode DMD3 may be a mode in which the second input 3000 is sensed.

In one or more embodiments of the present disclosure, the sensor driver 200C may first operate in the first operation mode DMD1. When the first input 2000 is sensed in the first operation mode DMD1, the sensor driver 200C may be switched (or changed) to the second operation mode DMD2. Alternatively, when the second input 3000 is sensed in the first operation mode DMD1, the sensor driver 200C may be switched (or changed) to the third operation mode DMD3.

In one or more embodiments of the present disclosure, when the second input 3000 is sensed in the second operation mode DMD2, the sensor driver 200C may be switched to the third operation mode DMD3. When the first input 2000 is deactivated (or not detected) in the second operation mode DMD2, the sensor driver 200C may be switched to the first operation mode DMD1. When the second input 3000 is deactivated (or not detected) in the third operation mode DMD3, the sensor driver 200C may be switched to the first operation mode DMD1.

FIG. 21 is a diagram illustrating the operation of the sensor driver 200C (see FIG. 6) according to one or more embodiments of the present disclosure.

Referring to FIG. 6, FIG. 20, and FIG. 21, for example, operations in the first to third operation modes DMD1, DMD2, and DMD3 are illustrated in the time (t) sequence.

In the first operation mode DMD1, the sensor driver 200C may be repeatedly driven in a second mode MD2-d and a first mode MD1-d. During the second mode MD2-d, the sensor layer 200 may be scan-driven to detect the second input 3000. During the first mode MD1-d, the sensor layer 200 may be scan-driven to detect the first input 2000. For example, FIG. 21 illustrates that the sensor driver 200C operates in the first mode MD1-d continuously after the second mode MD2-d, but the order is not limited thereto.

In the second operation mode DMD2, the sensor driver 200C may be repeatedly driven in the second mode MD2-d and a first mode MD1. During the second mode MD2-d, the sensor layer 200 may be scan-driven to detect the second input 3000. During the first mode MD1, the sensor layer 200 may be scan-driven to detect coordinates of the first input 2000.

In the third operation mode DMD3, the sensor driver 200C may be driven in a second mode MD2. During the second mode MD2, the sensor layer 200 may be scan-driven to detect coordinates of the second input 3000. In the third operation mode DMD3, the sensor driver 200C may not operate in the first mode MD1-d or MD1 until the second input 3000 is deactivated (or not detected).

Referring to FIG. 8, in the first modes MD1-d and MD1, the third electrodes 230, the first auxiliary electrodes 240-1, and the second auxiliary electrodes 240-2 may all be grounded or may have a constant voltage applied. Alternatively, in the first modes MD1-d and MD1, the third electrodes 230, the first auxiliary electrodes 240-1, and the second auxiliary electrodes 240-2 may all be floating (or electrically floating). Alternatively, in the first modes MD1-d and MD1, the third electrodes 230, the first auxiliary electrodes 240-1, and the second auxiliary electrodes 240-2 may have in-phase signals provided from the first electrodes 210 applied. In this case, touch noise may be reduced or prevented from entering through the third electrodes 230, the first auxiliary electrodes 240-1, and the second auxiliary electrodes 240-2.

In the second mode MD2-d and the second mode MD2, one end of each of the third electrodes 230, the first auxiliary electrodes 240-1, and the second auxiliary electrodes 240-2 may all be floating. Additionally, in the second modes MD2-d and MD2, the other end of each of the third electrodes 230, the first auxiliary electrodes 240-1, and the second auxiliary electrodes 240-2 may all be grounded or floating. Therefore, the compensation of the sensing signals by the coupling between the first electrodes 210 and the third electrodes 230, and between the second electrodes 220 and the first and second auxiliary electrodes 240-1, 240-2, may be improved or maximized.

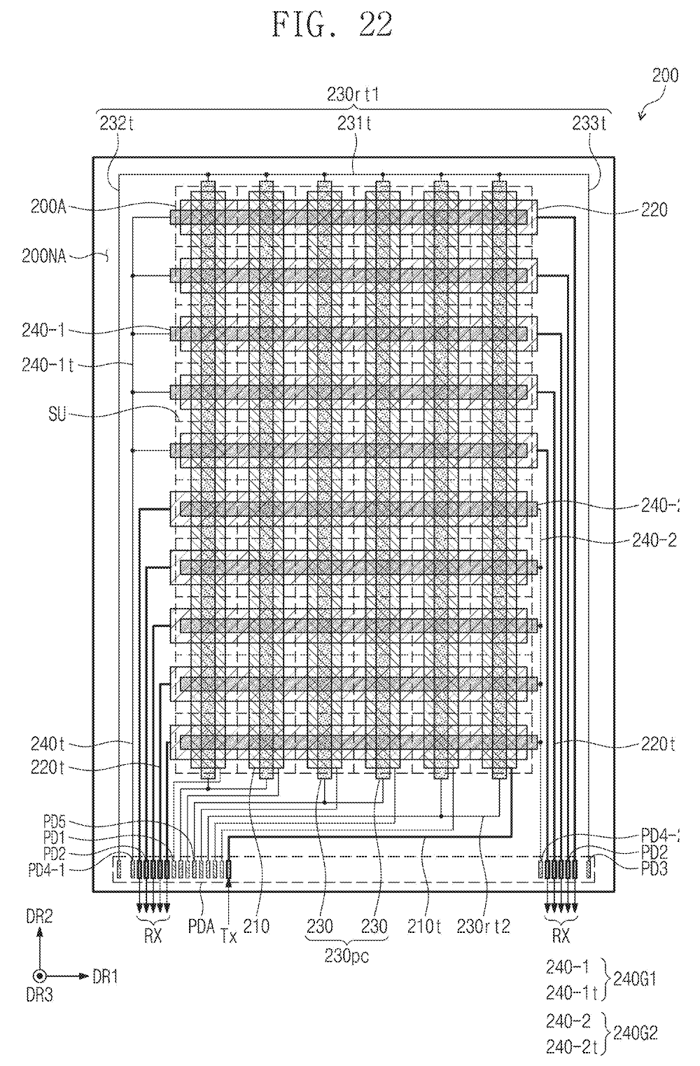

FIG. 22 is a view for explaining the first mode according to one or more embodiments of the present disclosure.

Referring to FIG. 6, FIG. 21, and FIG. 22, the first mode MD1-d of the first operation mode DMD1 and the first mode MD1 of the second operation mode DMD2 may include a mutual capacitance detection mode. FIG. 22 is a diagram for explaining the mutual capacitance detection mode in the first mode MD1-d of the first operation mode DMD1 and the first mode MD1 of the second operation mode DMD2.

In the mutual capacitance detection mode, the sensor driver 200C may sequentially provide a transmission signal TX through the first electrodes 210 and detect the coordinates of the first input 2000 using a received signal RX detected through the second electrodes 220. For example, the sensor driver 200C may be configured to sense the change in the mutual capacitance between the first electrodes 210 and the second electrodes 220 to calculate the input coordinates.

In FIG. 22, for example, one of the first electrodes 210 is illustrating as providing the transmission signal TX, and the received signal RX is output from the second electrodes 220. To clarify the signal representation, one of the first electrodes 210 providing the transmission signal TX is highlighted in FIG. 22. The sensor driver 200C may sense the change in the capacitance between the first electrode 210 and each of the second electrodes 220 to detect the input coordinates of the first input 2000.

In one or more other embodiments of the present disclosure, at least one of the first mode MD1-d of the first operation mode DMD1 or the first mode MD1 of the second operation mode DMD2 may further include a self-capacitance detection mode. In the self-capacitance detection mode, the sensor driver 200C may output driving signals to the first electrodes 210 and the second electrodes 220, and may be configured to sense the change in the capacitance of each of the first electrodes 210 and the second electrodes 220 to calculate the input coordinates.

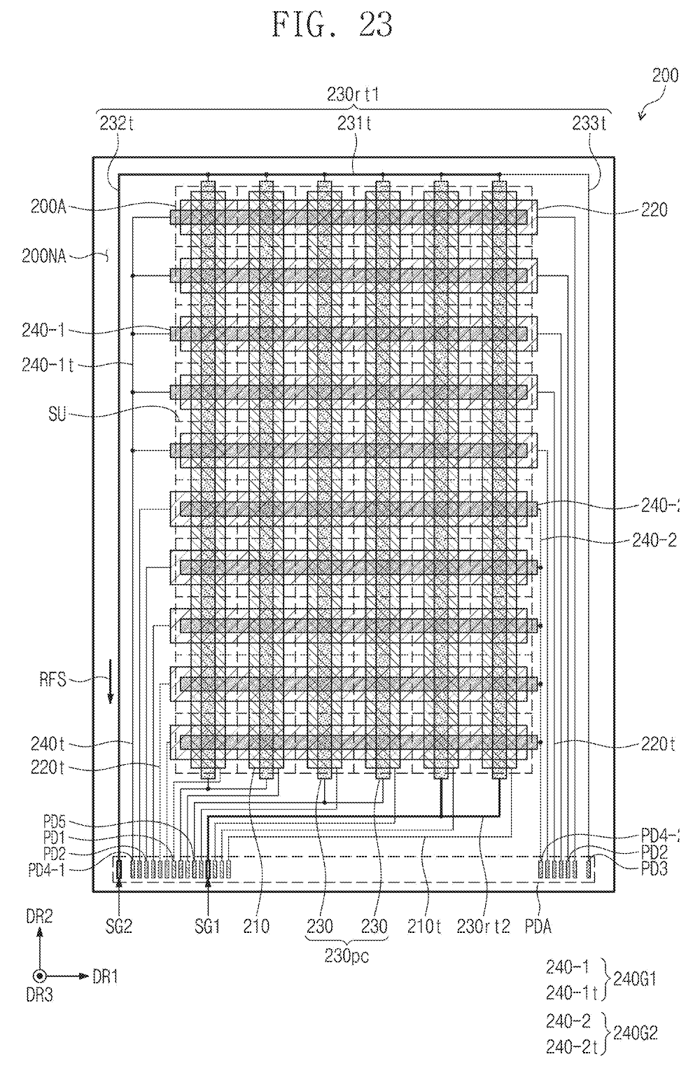

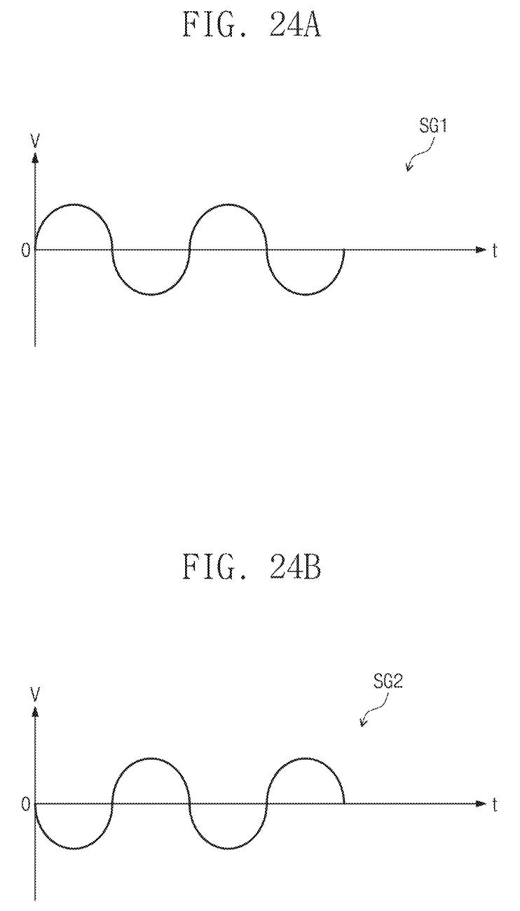

FIG. 23 is a diagram for explaining the second mode of the present disclosure, particularly a charging driving mode. FIG. 24A shows a graph illustrating the waveform of a first signal according to one or more embodiments of the present disclosure. FIG. 24B is a graph illustrating the waveform of a second signal according to one or more embodiments of the present disclosure.

Referring to FIG. 23, FIG. 24A, and FIG. 24B, the second mode MD2 may include the charging driving mode. The charging driving mode may include a searching charging driving mode and a tracking charging driving mode.

The searching charging driving mode may be a driving mode before sensing the position of the pen. Therefore, a first signal SG1 or a second signal SG2 may be sequentially provided through all the channels included in the sensor layer 200. That is, in the searching charging driving mode, the entire area of the sensor layer 200 may be sequentially scanned. When the pen PN is sensed in the searching charging driving mode, the sensor layer 200 may be charged in the tracking charging driving mode. For example, in the tracking charging driving mode, the sensor driver 200C may sequentially output the first signal SG1 and the second signal SG2 to an area overlapping with a point in which the pen PN was sensed, rather than the entire sensor layer 200.

In the charging driving mode, the sensor driver 200C may apply the first signal SG1 to one of the third pads PD3 and fifth pads PD5, and apply the second signal SG2 to the other pad. The second signal SG2 may be an inverted signal of the first signal SG1. For example, the first signal SG1 may be a sine wave signal.

Because the first signal SG1 and the second signal SG2 are applied to at least two pads, current RFS may have a current path flowing from one pad to the other pad. Also, because the first signal SG1 and the second signal SG2 are inverted sine wave signals, a direction of the current RFS may periodically change. In one or more other embodiments of the present disclosure, the first signal SG1 and the second signal SG2 may be square wave signals that are inverted from each other.

When the first signal SG1 and the second signal SG2 have an inverted relationship, noise caused by the first signal SG1 on the display layer 100 (see FIG. 4) may be canceled by noise caused by the second signal SG2. Therefore, flicker may not occur on the display layer 100, and the display quality of the display layer 100 may improve.

In one or more other embodiments of the present disclosure, the first signal SG1 may be a sine wave signal. However, it is not limited thereto, and the first signal SG1 may be a square wave signal, and the second signal SG2 may have a corresponding constant voltage. For example, the second signal SG2 may be a ground voltage. That is, the pad to which the second signal SG2 is applied may be considered as grounded. Even in this case, the current RFS may flow from one pad to the other pad. Additionally, even when the other pad is grounded, the direction of current RFS may periodically change because the first signal SG1 is a sine wave signal or a square wave signal.

Referring to FIG. 23, the second signal SG2 is provided to one of the third pads PD3 connected to the first loop trace line 230rt1, and the first signal SG1 is provided to one of the fifth pads PD5 connected to the third electrode 230. The current RFS may flow through a current path defined by the fifth pads PD5, the second loop trace line 230rt2 connected to the fifth pads PD5, the third electrode 230, a portion of the first loop trace line 230rt1 connected to the third pads PD3, and the third pads PD3. The current path may have a coil shape. Thus, in the charging driving mode of the second mode, the resonance circuit of the pen PN may be charged through the current path.

According to the present disclosure, the current path of the loop coil pattern may be implemented by the components included in the sensor layer 200. Thus, the electronic device 1000 (see FIG. 2A) may charge the pen PN using the sensor layer 200. Therefore, because a component including the coil for charging the pen PN does not need to be added separately, an increase in thickness, weight, and a decrease in flexibility of the electronic device 1000 may not occur.

In the charging driving mode, the first electrodes 210, second electrodes 220, first auxiliary electrodes 240-1, and second auxiliary electrodes 240-2 may be grounded, have a constant voltage applied, or be electrically floating. For example, the first electrodes 210, second electrodes 220, first auxiliary electrodes 240-1, and second auxiliary electrodes 240-2 may be floating. In this case, current RFS may not flow through the first electrodes 210, second electrodes 220, first auxiliary electrodes 240-1, and second auxiliary electrodes 240-2.

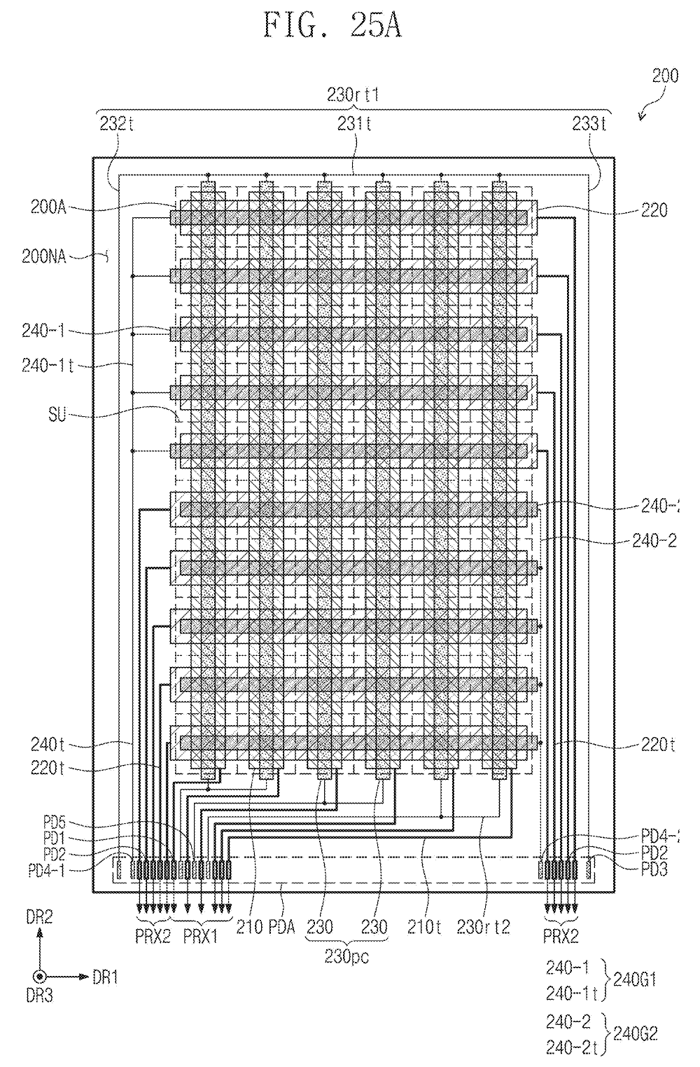

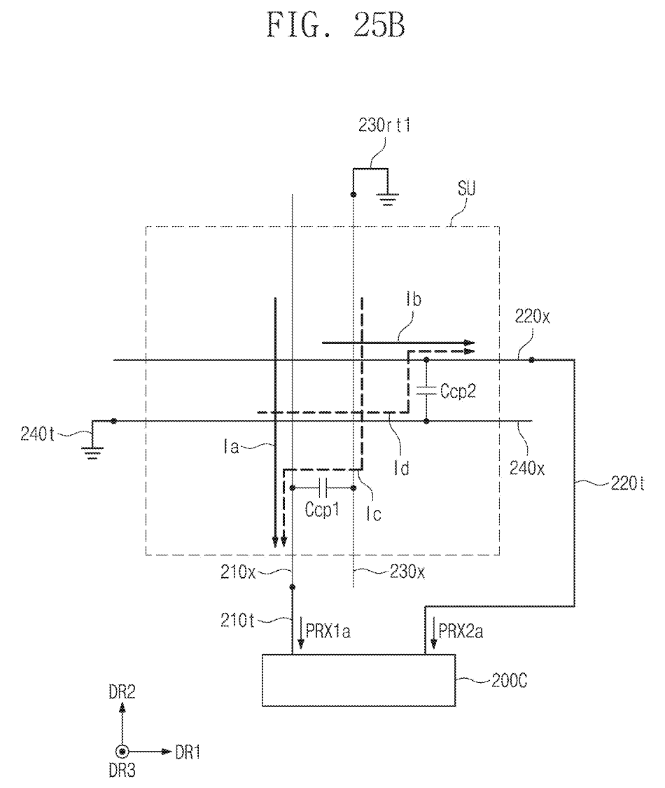

FIG. 25A is a view for explaining the second mode according to one or more embodiments of the present disclosure. FIG. 25B is a view for explaining the second mode based on a single sensing unit according to one or more embodiments of the present disclosure.

Referring to FIG. 25A and FIG. 25B, the second mode MD2 may include a charging driving mode and a pen-sensing driving mode. FIG. 25A and FIG. 25B are diagrams for explaining the pen-sensing driving mode.

Referring to FIG. 25A, in the pen-sensing driving mode, first received signals PRX1 may be output from the first electrodes 210, and second received signals PRX2 may be output from the second electrodes 220. FIG. 25B illustrates a single sensing unit SU in which first to fourth induced currents Ia, Ib, Ic and Id generated by the pen PN are flowing.

Referring to FIG. 25A and FIG. 25B, in one or more embodiments of the present disclosure, routing directions of one electrode and the other electrode in the sensor layer 200, which overlap each other, may differ. For example, a routing direction of a first electrode 210x and a routing direction of a third electrode 230x may be different. Additionally, a routing direction of a second electrode 220x and a routing direction of a fourth electrode 240x may be different. For example, in FIG. 25B, the first electrode 210x and the first trace line 210t may be connected to each other in a lower portion of the sensing unit SU, and the third electrode 230x and the first loop trace line 230rt1 may be connected to each other in an upper portion of the sensing unit SU. The second electrode 220x and the second trace line 220t may be connected to each other at a right side of the sensing unit SU, and the fourth electrode 240x and the fourth trace line 240t may be connected to each other at a left side of the sensing unit SU. The fourth trace line 240t may be the first auxiliary trace line 240-1t described in FIG. 8.

The RLC resonance circuit of the pen PN may emit a magnetic field at the resonant frequency while discharging the charged electric charge. The first induced current Ia may be generated in the first electrode 210x by the magnetic field provided from the pen PN, and the second induced current Ib may be generated in the second electrode 220x. Additionally, the third induced current Ic may be generated in the third electrode 230x, and the fourth induced current Id may be generated in the fourth electrode 240x.

A first coupling capacitor Ccp1 may be located between the third electrode 230x and the first electrode 210x, and a second coupling capacitor Ccp2 may be located between the fourth electrode 240x and the second electrode 220x. The third induced current Ic may be transferred to the first electrode 210x through the first coupling capacitor Ccp1, and the fourth induced current Id may be transferred to the second electrode 220x through the second coupling capacitor Ccp2.

The sensor driver 200C may receive a first received signal PRX1a based on the first induced current Ia and the third induced current Ic from the first electrode 210x, and may receive a second received signal PRX2a based on the second induced current Ib and the fourth induced current Id from the second electrode 220x. The sensor driver 200C may detect the input coordinates of the pen PN based on the first received signal PRX1a and the second received signal PRX2a.

The sensor driver 200C may receive the first received signal PRX1a from the first electrode 210x and the second received signal PRX2a from the second electrode 220x. At this time, one ends of the third electrode 230x and the fourth electrode 240x may be floating. Thus, the compensation of the sensing signal may be improved or maximized by the coupling between the first electrode 210x and the third electrode 230x, and between the second electrode 220x and the fourth electrode 240x.

Additionally, the other ends of the third electrode 230x and the fourth electrode 240x may be grounded or floating. Thus, the third induced current Ic and the fourth induced current Id may be sufficiently transferred to the first electrode 210x and the second electrode 220x by the coupling between the first electrode 210x and the third electrode 230x, and between the second electrode 220x and the fourth electrode 240x.

According to the above-described present disclosure, the first impedance of the first auxiliary electrode group and the second impedance of the second auxiliary electrode group may be matched to be substantially identical. In this case, the deviation in the amount of change in mutual capacitance between the first electrode and the second electrode, caused by the first auxiliary electrode group and the second auxiliary electrode group, may be reduced or minimized. As the deviation decreases, the probability of touch malfunctions may be reduced or eliminated. As a result, the touch reliability of the sensor layer may be improved.

Although the present disclosure has been described with reference to the embodiments, it will be understood that various changes and modifications of the present disclosure may be made by one ordinary skilled in the art or one having ordinary knowledge in the art without departing from the spirit and technical field of the disclosure as hereinafter claimed.

Hence, the real protective scope of the present disclosure shall be determined by the technical scope of the accompanying claims, with functional equivalents thereof to be included therein.

What is claimed is:

1. An electronic device comprising:
a display layer; and
a sensor layer above the display layer and comprising:
first electrodes arranged along a first direction;
second electrodes crossing the first electrodes and arranged along a second direction crossing the first direction;
a first auxiliary electrode group comprising first auxiliary electrodes arranged along the second direction, and a first auxiliary trace line electrically connected to the first auxiliary electrodes; and
a second auxiliary electrode group having an impedance that is substantially equal to an impedance of the first auxiliary electrode group, and comprising second auxiliary electrodes arranged along the second direction, and a second auxiliary trace line electrically connected to the second auxiliary electrodes.

2. The electronic device according to claim 1, wherein the sensor layer further comprises a first pad connected to the first auxiliary trace line, and a second pad connected to the second auxiliary trace line, and
wherein the second auxiliary electrodes are between the first auxiliary electrodes and a pad area at which the first pad and the second pad are located.

3. The electronic device according to claim 1, wherein the first auxiliary electrodes comprise a first auxiliary electrode,
wherein the second auxiliary electrodes comprise a second auxiliary electrode,
wherein the first electrodes comprise a first electrode crossing the first auxiliary electrode and the second auxiliary electrode, and
wherein the second electrodes comprise a (2-1)-th electrode overlapping the first auxiliary electrode, and a (2-2)-th electrode overlapping the second auxiliary electrode.

4. The electronic device according to claim 3, wherein a resistance of the first auxiliary electrode is substantially equal to a resistance of the second auxiliary electrode, and
wherein a resistance of the first auxiliary trace line is substantially equal to a resistance of the second auxiliary trace line.

5. The electronic device according to claim 3, wherein a capacitance between the first auxiliary electrode and the first electrode is substantially equal to a capacitance between the second auxiliary electrode and the first electrode.

6. The electronic device according to claim 3, wherein a capacitance between the first auxiliary electrode and the (2-1)-th electrode is substantially equal to a capacitance between the second auxiliary electrode and the (2-2)-th electrode.

7. The electronic device according to claim 3, wherein a first base capacitance corresponding to the first auxiliary electrode is substantially equal to a second base capacitance corresponding to the second auxiliary electrode.

8. The electronic device according to claim 3, wherein the first auxiliary trace line has a resistance that is greater than a resistance of the second auxiliary trace line, and
wherein the first auxiliary electrode has a resistance that is less than a resistance of the second auxiliary electrode.

9. The electronic device according to claim 3, wherein a resistance of the first auxiliary trace line is greater than a resistance of the second auxiliary trace line, and
wherein a capacitance corresponding to the first auxiliary electrode is less than a capacitance corresponding to the second auxiliary electrode.

10. The electronic device according to claim 9, wherein a capacitance between the first auxiliary electrode and the first electrode is less than a capacitance between the second auxiliary electrode and the first electrode.

11. The electronic device according to claim 9, wherein a capacitance between the first auxiliary electrode and the (2-1)-th electrode is less than a capacitance between the second auxiliary electrode and the (2-2)-th electrode.

12. The electronic device according to claim 9, wherein a first base capacitance corresponding to the first auxiliary electrode is less than a second base capacitance corresponding to the second auxiliary electrode.

13. The electronic device according to claim 3, wherein the first auxiliary electrode has a first mesh structure,
wherein the second auxiliary electrode has a second mesh structure,
wherein, within a region, a surface area occupied by the first mesh structure is greater than a surface area occupied by the second mesh structure.

14. The electronic device according to claim 3, wherein the first auxiliary electrode comprises:
a first auxiliary pattern; and
an additional auxiliary pattern at a different layer from a layer at which the first auxiliary pattern is located, and electrically connected to the first auxiliary pattern.

15. The electronic device according to claim 3, wherein the sensor layer further comprises an insulating layer,
wherein the first electrode comprises first sensing patterns above the insulating layer, and a first bridge pattern between the insulating layer and the display layer and connected to the first sensing patterns,
wherein the second auxiliary electrode comprises a (2-1)-th layer auxiliary electrode between the insulating layer and the display layer, and a (2-2)-th layer auxiliary electrode above the (2-1)-th layer auxiliary electrode, and
wherein a capacitance between the first auxiliary electrode and the first electrode is less than a capacitance between the second auxiliary electrode and the first electrode.

16. The electronic device according to claim 15, wherein the insulating layer comprises an organic layer.

17. The electronic device according to claim 15, wherein a portion of the second auxiliary electrode between the display layer and the insulating layer has a surface area that is greater than a surface area of a portion of the first auxiliary electrode between the display layer and the insulating layer.

18. The electronic device according to claim 1, further comprising a sensor driver configured to drive the sensor layer,
wherein the sensor layer further comprises third electrodes arranged along the first direction to overlap the first electrodes, and
wherein the sensor driver is further configured to selectively operate in a first mode for sensing a touch input, and a second mode for sensing a pen input and comprising:
a charging driving mode wherein the sensor driver is configured to provide a first signal to at least one of the third electrodes, and to provide a second signal to at least another one of the third electrodes; and
a pen-sensing driving mode wherein the sensor driver is configured to receive first reception signals from the first electrodes, and to receive second reception signals from the second electrodes.

19. An electronic device comprising:
first electrodes;
second electrodes crossing the first electrodes;
a first auxiliary electrode group comprising first auxiliary electrodes, and a first auxiliary trace line electrically connected to the first auxiliary electrodes; and
a second auxiliary electrode group having an impedance that is substantially equal to an impedance of the first auxiliary electrode group, and comprising second auxiliary electrodes, and a second auxiliary trace line electrically connected to the second auxiliary electrodes.

20. The electronic device according to claim 19, wherein a resistance of the first auxiliary electrode group is substantially equal to a resistance of the second auxiliary electrode group, and a capacitive reactance of the first auxiliary electrode group is substantially equal to a capacitive reactance of the second auxiliary electrode group, or wherein the first auxiliary electrode group has resistance that is greater than a resistance of the second auxiliary electrode group, and the first auxiliary electrode group has a capacitive reactance that is less than a capacitive reactance of the second auxiliary electrode group.
